(19) United States
(12) Patent Application Publication
(10) Pub. No.: US 2023/0420441 A1
(43) Pub. Date: Dec. 28, 2023

(54) DISPLAY DEVICE

(71) Applicant: SONY SEMICONDUCTOR SOLUTIONS CORPORATION, Kanagawa (JP)

(72) Inventors: Norifumi KIKUCHI, Kanagawa (JP); Hisao SAKURAI, Kanagawa (JP); Ippei NISHINAKA, Kanagawa (JP)

(73) Assignee: SONY SEMICONDUCTOR SOLUTIONS CORPORATION, Kanagawa (JP)

(21) Appl. No.: 18/247,350

(22) PCT Filed: Oct. 4, 2021
(86) PCT No.: PCT/JP2021/036647

§ 371 Date: Mar. 30, 2023

(30) Foreign Application Priority Data
Oct. 6, 2020 (JP) 2020-169450

(51) Int. Cl. H01L 25/18; H01L 23/538

(52) U.S. Cl. CPC H01L 25/18; H01L 23/5386

(57) ABSTRACT

Provided is a display device which enables a reduction in the number of signal lines. A display device includes: a substrate; multiple pixels that are provided on the substrate and form multiple columns; and multiple signal lines that are provided on the substrate and extend in a column direction. The multiple pixels include at least one of multiple first pixels having light emitting diode elements of three colors or multiple second pixels having light emitting diode elements of two colors. The number of the signal lines is two per column.

### TECHNICAL FIELD

The present disclosure relates to a display device.

### BACKGROUND ART

In recent years, an LED display device in which multiple light emitting diode elements (hereinafter, referred to as “LED elements”) are two-dimensionally arranged has been widely known. In the LED display device, one pixel usually includes LED elements of three colors of red (R), green (G), and blue (B) (see, for example, Patent Document 1).

### CITATION LIST

### Patent Document

Patent Document 1: Japanese Patent Application Laid-Open No. 2001-75508

### SUMMARY OF THE INVENTION

### Problems to be Solved by the Invention

In the LED display device in which one pixel includes LED elements of three colors, however, three signal lines are provided per pixel column, there is a problem that the number of signal lines on a substrate is large and a wiring rule of the signal lines becomes complicated.

An object of the present disclosure is to provide a display device capable of reducing the number of signal lines.

### Solutions to Problems

In order to solve the above problem, a first disclosure relates to a display device including:
a substrate;
multiple pixels that are provided on the substrate and form multiple columns; and
multiple signal lines that are provided on the substrate and extend in a column direction,
the multiple pixels including at least one of multiple first pixels having light emitting diode elements of three colors or multiple second pixels having light emitting diode elements of two colors, and
a number of the signal lines being two per column.

A second disclosure relates to a display device including:
a substrate;
multiple pixels that are provided on the substrate and form multiple columns; and
multiple signal lines that are provided on the substrate and extend in a column direction,
the multiple pixels including at least one of multiple first pixels including light sources of three colors or multiple second pixels including light sources of two colors,
the light sources of the two colors respectively including light emitting diode elements,
the light sources of the three colors respectively including light emitting diode elements, and
a number of the signal lines being two per column.

In the second disclosure, the first pixel may include a first color light source, a second color light source, and a third color light source.

In the second disclosure, the multiple second pixels may include multiple third pixels and multiple fourth pixels, the third pixel may include a first color light source and a second color light source, the fourth pixel may include a second color light source and a third color light source, and the third pixels and the fourth pixels may be alternately arranged in the column direction and alternately arranged in the row direction.

In the second disclosure, the multiple pixels may include multiple first pixels and multiple second pixels, the first pixel may include a first color light source, a second color light source, and a third color light source, the second pixel may include a first color light source and a second color light source, and the first pixels and the second pixels may be alternately arranged in the column direction and alternately arranged in the row direction.

In the second disclosure, the first color light source, the second color light source, and the third color light source are configured to emit first color light, second color light, and third color light, respectively. The first color light source may be a red light source configured to emit red light. The second color light source may be a green light source configured to emit green light. The third color light source may be a blue light source configured to emit blue light. The red light source may have a red LED element, have a white LED element and a red filter, or have a blue LED element and a color conversion layer that converts blue light emitted from the blue LED element into red light. The green light source may have a green LED element, have a white LED element and a green filter, or have a blue LED element and a color conversion layer that converts blue light emitted from the blue LED element into green light. The blue light source may have a blue LED element, or may have a white LED element and a blue filter.

### BRIEF DESCRIPTION OF DRAWINGS

FIG. 1 is a plan view illustrating an example of a configuration of a display device according to a first embodiment of the present disclosure.

FIG. 2 is a plan view illustrating an example of a circuit of a portion indicated by a region R1 in FIG. 1.

FIG. 3 is a plan view illustrating an example of a configuration of a surface mount device.

FIG. 4 is a plan view illustrating an example of a configuration of a display device according to a comparative example.

FIG. 5 is a diagram illustrating an example of a circuit of a portion illustrated in a region R1 of FIG. 4.

FIG. 6 is a plan view illustrating an example of a configuration of a display device according to a modified example.

FIG. 7 is a diagram illustrating an example of a circuit of a portion illustrated in a region R1 of FIG. 6.

FIG. 8 is a plan view illustrating an example of a configuration of a display device according to a modified example.

FIG. 9 is a diagram illustrating an example of a circuit of a portion illustrated in a region R1 of FIG. 8.

FIG. 10 is a plan view illustrating an example of a configuration of a display device according to a modified example.

FIG. 11 is a diagram illustrating an example of a circuit of a portion illustrated in a region R1 of FIG. 10.

FIG. 12 is a plan view illustrating an example of a configuration of a display device according to a modified example.

FIG. 13 is a diagram illustrating an example of a circuit of a portion illustrated in a region R1 of FIG. 12.

FIG. 14 is a plan view illustrating an example of signal lines and scanning lines of a display device according to a modified example.

FIG. 15 is a plan view illustrating an example of signal lines and scanning lines of the display device according to the comparative example.

FIG. 16 is a plan view illustrating an example of a configuration of a display device according to a modified example.

FIG. 17 is a diagram illustrating an example of a circuit of a portion illustrated in a region R1 of FIG. 16.

FIG. 18 is a plan view illustrating an example of a configuration of a surface mount device.

FIG. 19 is a cross-sectional view illustrating a first configuration example of a red light source, a green light source, and a blue light source included in a pixel.

FIG. 20 is a cross-sectional view illustrating a second configuration example of the red light source, the green light source, and the blue light source included in the pixel.

FIG. 21 is a plan view illustrating an example of a configuration of a display device according to a second embodiment of the present disclosure.

FIG. 22 is a plan view illustrating an example of a circuit of a portion indicated by a region R1 in FIG. 21.

FIGS. 23A and 23B are plan views each illustrating an example of a configuration of a surface mount device.

FIG. 24 is a plan view illustrating an example of a configuration of a display device according to a third embodiment of the present disclosure.

FIG. 25 is a plan view illustrating an example of a circuit of a portion indicated by a region R1 in FIG. 24.

FIG. 26 is a plan view illustrating an example of a configuration of a display device according to a modified example.

FIG. 27 is a diagram illustrating an example of a circuit of a portion illustrated in a region R1 of FIG. 26.

FIG. 28 is a plan view illustrating an example of a configuration of a display device according to a fourth embodiment of the present disclosure.

FIG. 29 is a plan view illustrating an example of a circuit of a portion indicated by a region R1 in FIG. 28.

FIG. 30 is a plan view illustrating an example of a configuration of a surface mount device.

FIG. 31 is a cross-sectional view illustrating the example of the configuration of the surface mount device.

FIG. 32 is a plan view illustrating an example of a configuration of a display device according to a modified example.

FIG. 33 is a plan view illustrating an example of a configuration of a surface mount device.

FIG. 34 is a diagram illustrating an example of a circuit of a portion illustrated in a region R1 of FIG. 32.

### MODE FOR CARRYING OUT THE INVENTION

Embodiments of the present disclosure will be described in the following order. Note that the same or corresponding portions will be denoted by the same reference signs in all the drawings of the following embodiments.
1 First Embodiment (Example of Display Device in Which Multiple Pixels Having LED Elements of Three Colors Are Two-Dimensionally Arrayed)
2 Second Embodiment (Example of Display Device in Which Multiple Pixels Having LED Elements of Two Colors are Two-Dimensionally Arrayed)
3 Third Embodiment (Example of Display Device in Which Multiple Pixels Having LED Elements of Two Colors and Multiple Pixels Having LED Elements of Three Colors Are Two-Dimensionally Arranged)
4 Fourth Embodiment (Example of Display Device in Which Resistance Element Is Connected to Each of LED Elements of Two Colors Among LED Elements of Three Colors)

### 1 First Embodiment

### [Configuration of Display Device]

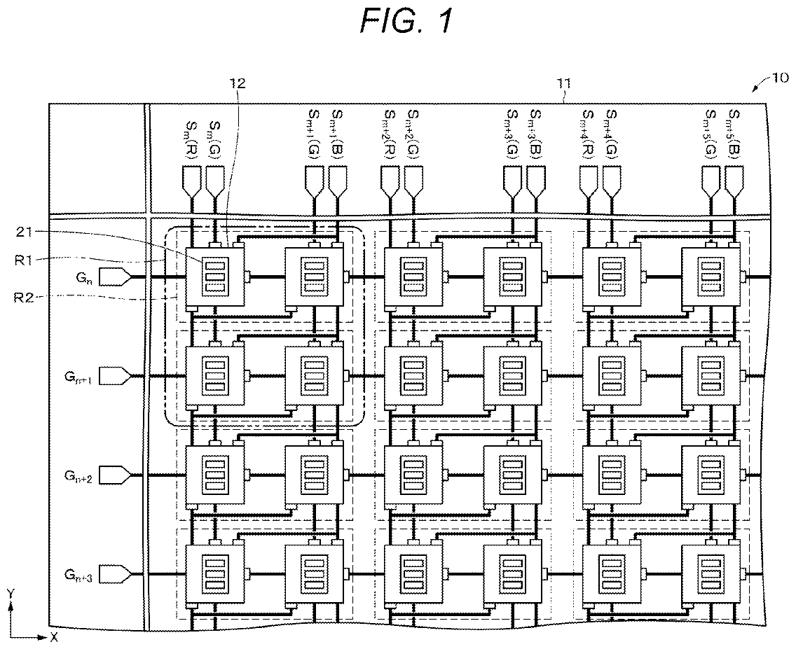

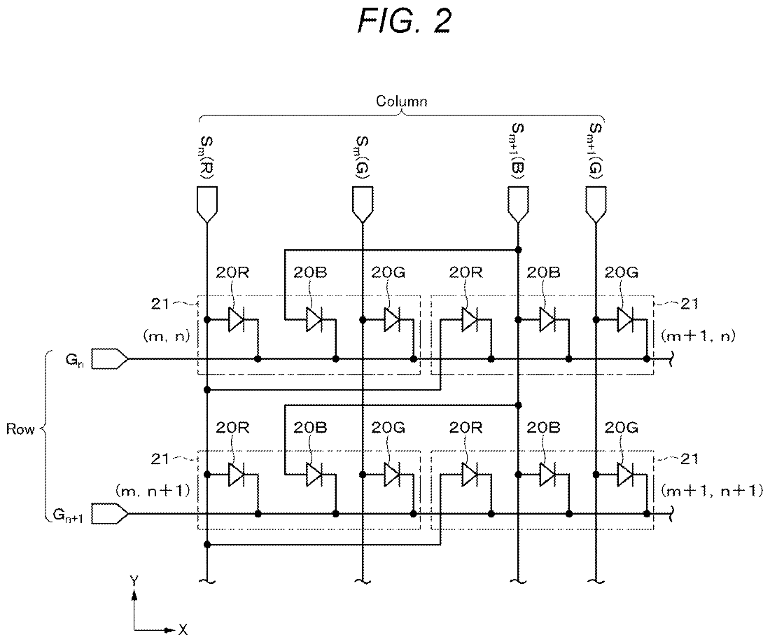

FIG. 1 is a plan view illustrating an example of a configuration of a display device 10 according to a first embodiment of the present disclosure. FIG. 2 is a view illustrating an example of a circuit of a portion illustrated in a region R1 of FIG. 1. The display device 10 is a so-called LED display device, and includes a substrate 11, multiple surface mount devices (referred to as “SMDs”) 12 arranged on the substrate 11, and multiple signal lines S₁(R), S₃(R), . . . , Sₘ₋₂(R), and Sₘ(R), multiple signal lines S₁(G), S₂(G), . . . , Sₘ₋₁(G), Sₘ(G), Sₘ₊₁(G), multiple signal lines S₂(B), S₄(B), . . . , Sₘ₋₁(B), and Sₘ₊₁(B), and multiple scanning lines G₁, G₂, . . . , Gₙ which are arranged on the substrate 11. The display device 10 may further include a driver integrated circuit (IC) arranged on the substrate 11. The display device 10 may be a fine pitch display having a pixel pitch of 1 mm or less.

In the following description, the signal lines S₁(R), S₃(R), . . . , Sₘ₋₂(R), and Sₘ(R) will be collectively referred to as signal lines S(R), the signal lines S₁(G), S₂(G), . . . , Sₘ₋₁(G), Sₘ(G), and Sₘ₊₁(G) will be collectively referred to as signal lines S(G), and the signal lines S₂(B), S₄(B), . . . , Sₘ₋₁(B), and Sₘ₊₁(B) will be collectively referred to as signal lines S(B). The signal lines S(R), the signal lines S(G), and the signal lines S(B) will be collectively referred to as signal lines S. The scanning lines G₁, G₂, . . . , and Gₙ will be collectively referred to as scanning lines G.

### (Substrate)

The substrate 11 is, for example, a glass substrate or a resin substrate. The glass substrate contains, for example, at least one selected from the group consisting of high-strain-point glass, soda glass, borosilicate glass, forsterite, lead glass, quartz glass, and the like. The resin substrate contains, for example, at least one polymer resin selected from the group consisting of polymethyl methacrylate, polyvinyl alcohol, polyvinyl phenol, polyether sulfone, polyimide, polycarbonate, polyethylene terephthalate, polyethylene naphthalate, and the like. The substrate 11 may have a planar shape or a curved shape. The substrate 11 may be a flexible substrate. In the present specification, a first direction and a second direction orthogonal to each other in a plane of the substrate 11 will be referred to as an X-axis direction and a Y-axis direction, respectively.

### (Signal Line and Scanning Line)

The multiple signal lines S(R), S(G), and S(B) extend in the Y-axis direction (second direction). The multiple scanning lines G extend in the X-axis direction (first direction). Pixels 21, that is, light emitting diodes (LED) elements 20R, 20G, and 20B are respectively driven by turning on and off the multiple signal lines S(R), S(G), and S(B), and the scanning lines G. The number of the scanning lines G is the same as the number of rows of the pixels 21. The number of the signal lines S is twice the number of columns of the pixels 21.

First pairs of the signal lines S(R) and S(G) and second pairs of the signal lines S(G) and S(B) are alternately arranged in the X-axis direction. The signal line S(R) is a signal line connected to the red LED element 20R. The signal line S(G) is a signal line connected to the green LED element 20G. The signal line S(B) is a signal line connected to the blue LED element 20B. The signal line S(R) is an example of a first signal line. The signal line S(G) is an example of a second signal line. The signal line S(B) is an example of a third signal line.

### (Driver IC)

The driver IC controls the multiple SMDs 12 via the multiple scanning lines G and multiple signal lines S(R), S(G), and S(B), thereby controlling image display of the display device 10.

### (SMD)

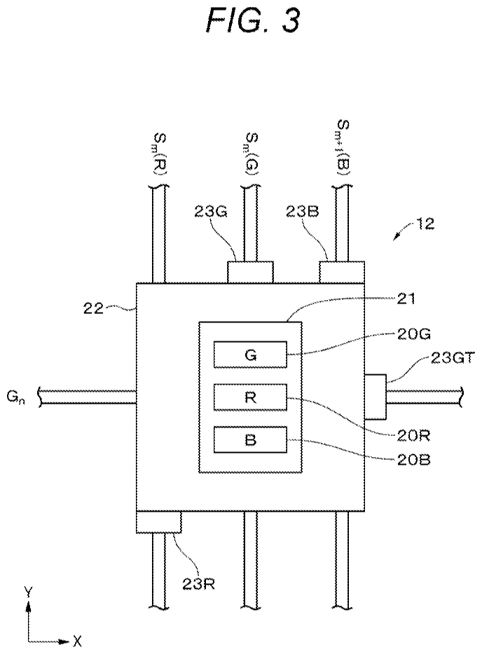

FIG. 3 is a plan view illustrating an example of a configuration of the SMD 12. The SMD 12 is an SMD (1 in 1 SMD) in which one pixel is configured in one chip. The SMD 12 includes one pixel (first pixel) 21 and a package 22.

The multiple SMDs 12 are two-dimensionally arranged in a matrix on the substrate 11 to form multiple rows and columns. Similarly, the multiple pixels 21 are two-dimensionally arranged in a matrix on the substrate 11 to form multiple rows and columns. A row direction and a column direction of the matrix-like array correspond to the X-axis direction and the Y-axis direction, respectively. In the following description, a position in the m-th column and the n-th row in the matrix-like two-dimensional arrangement will be referred to as a position (m, n). Furthermore, a column including multiple pixels 21 arranged in the Y-axis direction is referred to as a pixel column.

Each of the pixels 21 includes LED elements of three colors (light sources of three colors) 20R, 20G, and 20B. More specifically, each of the pixels 21 includes the red LED element 20R, the green LED element 20G, and the blue LED element 20B. In the following description, the red LED element 20R, the green LED element 20G, and the blue LED element 20B will be collectively referred to as LED elements 20.

The red LED element 20R is a red light source configured to capable of emitting red light. The green LED element 20G is a green light source configured to capable of emitting green light. The blue LED element 20B is a blue light source configured to capable of emitting blue light. The red LED element 20R is an example of an LED element of a first color. The green LED element 20G is an example of an LED element of a second color. The blue LED element 20B is an example of an LED element of a third color. The green LED element 20G is an LED element having the highest luminance among the red LED element 20R, the green LED element 20G, and the blue LED element 20B in a case where white display is performed.

The package 22 includes an anode terminal 23R, an anode terminal 23G, an anode terminal 23B, and a cathode terminal (gate terminal) 23GT. The anode terminal 23R is connected to the signal line S(R). The anode terminal 23G is connected to the signal line S(G). The anode terminal 23B is connected to the signal line S(B). The cathode terminal (gate terminal) 23GT is connected to the scanning line G.

The SMD 12 is of a common cathode type having a common cathode terminal. An anode of the red LED element 20R is connected to the anode terminal 23R. An anode of the green LED element 20G is connected to the anode terminal 23G. An anode of the blue LED element 20B is connected to the anode terminal 23B. Cathodes of the red LED element 20R, the green LED element 20G, and the blue LED element 20B are connected to the cathode terminal 23GT.

### [Connection Between LED Element and Each of Signal Line and Scanning Line]

Hereinafter, an example of connection between the LED element 20 and each of the signal line S and the scanning line G will be described with reference to FIG. 2.

The number of signal lines S(G) is one per pixel column. The number of signal lines columns. Therefore, the number of signal lines S is two per pixel column.

In a case where it is assumed that two adjacent pixel columns form a pair, the red LED elements 20R included in the respective pixels 21 forming the pair of two pixel columns share one signal line S(R). Furthermore, the blue LED elements 20B included in the respective pixels 21 forming the two pixel columns share one signal line S(B).

In a case where it is assumed that two pixels 21 adjacent in the X-axis direction form a pair, the red LED elements 20R respectively included in the two pixels 21 forming the pair share one signal line S(R). The blue LED elements 20B respectively included in the two pixels 21 forming the pair share one signal line S(B). Pairs of the multiple pixels 21 are two-dimensionally arranged in the X-axis direction and the Y-axis direction.

More specifically, the red LED elements 20R respectively included in the pixel 21 at the position (m, n) and the pixel 21 at a position (m+1, n) share one signal line Sₘ(R). Furthermore, the red LED elements 20R respectively included in the pixel 21 at a position (m, n+1) and the pixel 21 at a position (m+1, n+1) similarly share one signal line Sₘ(R). The blue LED elements 20B included in the pixel 21 at the position (m, n) and the blue LED element 20B included in the pixel 21 at the position (m+1, n) share one signal line Sₘ₊₁(B). Furthermore, similarly, the blue LED element 20B included in the pixel 21 at the position (m, n+1) and the blue LED element 20B included in the pixel 21 at the position (m+1, n+1) share one signal line Sₘ₊₁(B). In FIG. 1, broken-line frames R2 indicate pairs of the pixels 21 sharing the signal line Sₘ(R) and the signal line Sₘ₊₁(B).

An anode of the red LED element 20R included in the pixel 21 at the position (m, n) is connected to the signal line Sₘ(R) via the anode terminal 23R. An anode of the green LED element 20G included in the pixel 21 at the position (m, n) is connected to the signal line Sₘ(G) via the anode terminal 23G. An anode of the blue LED element 20B included in the pixel 21 at the position (m, n) is connected to the signal line Sₘ₊₁(B) via the anode terminal 23B. Cathodes of the red LED element 20R, the green LED element 20G, and the blue LED element 20B included in the pixel 21 at the position (m, n) are connected to the scanning line Gₙ via the cathode terminal 23GT.

An anode of the red LED element 20R included in the pixel 21 at the position (m+1, n) is connected to the signal line Sₘ(R) via the anode terminal 23R. An anode of the green LED element 20G included in the pixel 21 at the position (m+1, n) is connected to the signal line Sₘ₊₁(G) via the anode terminal 23G. An anode of the blue LED element 20B included in the pixel 21 at the position (m+1, n) is connected to the signal line Sₘ₊₁(B) via the anode terminal 23B. Cathodes of the red LED element 20R, the green LED element 20G, and the blue LED element 20B included in the pixel 21 at the position (m+1, n) are connected to the scanning line Gₙ via the cathode terminal 23GT.

A connection mode between each of the red LED element 20R, the green LED element and the blue LED element 20B included in the pixel 21 at the position (m, n+1) and each of the signal lines Sₘ(R), Sₘ(G), and Sₘ₊₁(B) is similar to that of the pixel 21 at the position (m, n).

A connection mode between each of the red LED element 20R, the green LED element and the blue LED element 20B included in the pixel 21 at the position (m+1, n+1) and each of the signal lines Sₘ(R), Sₘ₊₁(G), and Sₘ₊₁(B) is similar to that of the pixel 21 at the position (m+1, n).

The red LED element 20R included in a pixel 21A at the position (m, n) and the red LED element 20R included in the pixel 21 at the position (m+1, n) are connected in parallel. Similarly, the red LED element 20R included in the pixel 21A at the position (m, n+1) and the red LED element 20R included in the pixel 21 at the position (m+1, n+1) are connected in parallel. The blue LED element 20B included in the pixel 21 at the position (m, n) and the blue LED element 20B included in the pixel 21 at the position (m+1, n) are connected in parallel. Similarly, the blue LED element 20B included in the pixel 21 at the position (m, n+1) and the blue LED element 20B included in the pixel 21 at the position (m+1, n+1) are connected in parallel.

### [Functions and Effects]

Hereinafter, functions and effects will be described by comparing the display device 10 according to the first embodiment with a display device 110 according to a comparative example.

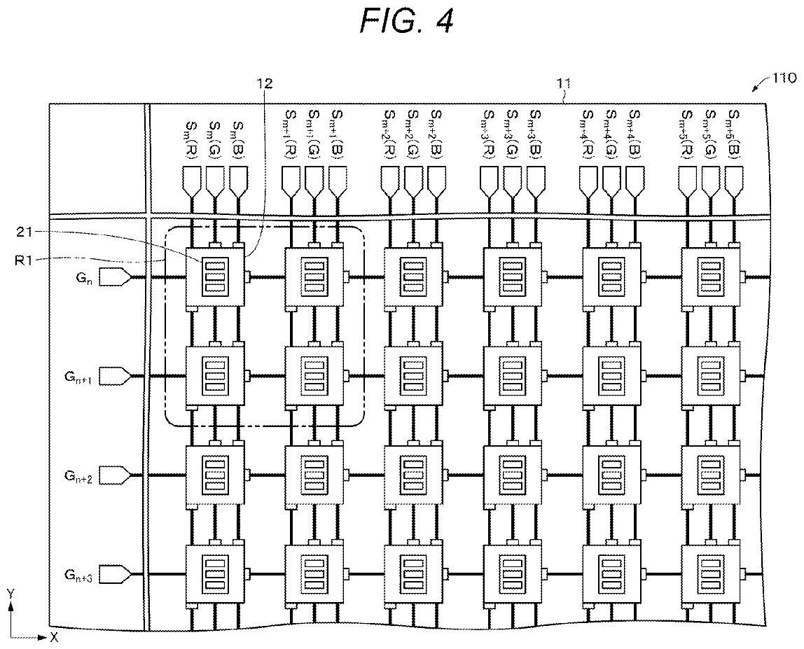

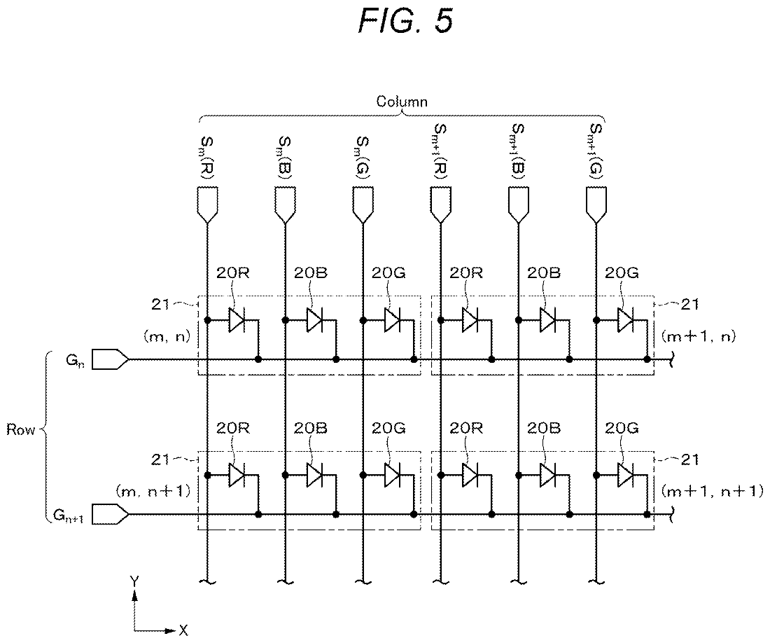

In the display device 110 according to the comparative example, a red LED element a green LED element 20G, and a blue LED element 20B included in each of pixels 21 forming one pixel column are connected to signal lines S(B) of signal lines S(R) and S(G) as illustrated in FIGS. 4 and 5. Therefore, the number of signal lines S is three per pixel column. Therefore, there is a problem that the number of signal lines S on a substrate 11 is large, and a wiring rule of the signal lines S becomes complicated.

In a case where it is assumed that two adjacent pixel columns form a pair in the display device 10 according to the first embodiment, as illustrated in FIGS. 1 and 2, the red LED elements included in the respectively pixels 21 forming a pair of two pixel columns share one signal line S(R). Furthermore, the blue LED elements 20B included in the respective pixels 21 forming the two pixel columns share one signal line S(B). Therefore, the number of the signal lines S(G) can be set to one per pixel column, and the number of the signal lines S(R) and the number of the signal lines S(B) can be set to one per two pixel columns. That is, the number of signal lines S can be set to two per pixel column. Therefore, since the number of signal lines S on the substrate 11 can be reduced, the wiring rule of the signal lines S can be relaxed. Therefore, the cost of the display device 10 can be reduced.

Furthermore, since the number of output signals can be reduced, the number of driving driver integrated circuits (ICs) can be reduced. Therefore, the cost of the display device 10 can be reduced.

Furthermore, the reduction in the number of the driving driver ICs described above leads to a reduction in the amount of heat generation (that is, power consumption) of the display device 10, and the luminance of the display device 10 can also be improved.

Furthermore, the total number of signals can be reduced to ⅔, video signal transmission, signal processing, or the like can also be reduced to ⅔. Therefore, the cost of the circuit of the display device 10 can be reduced.

### MODIFIED EXAMPLES

### Modified Example 1

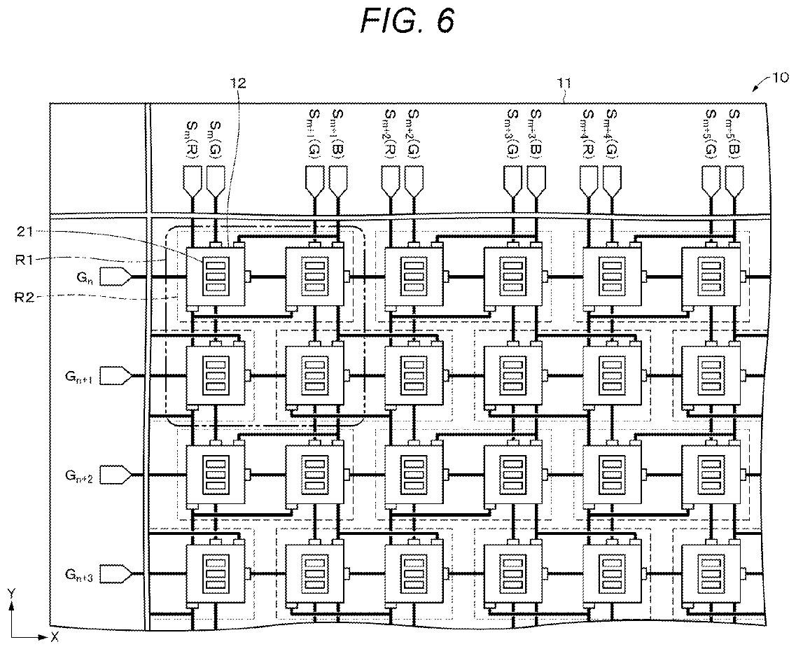

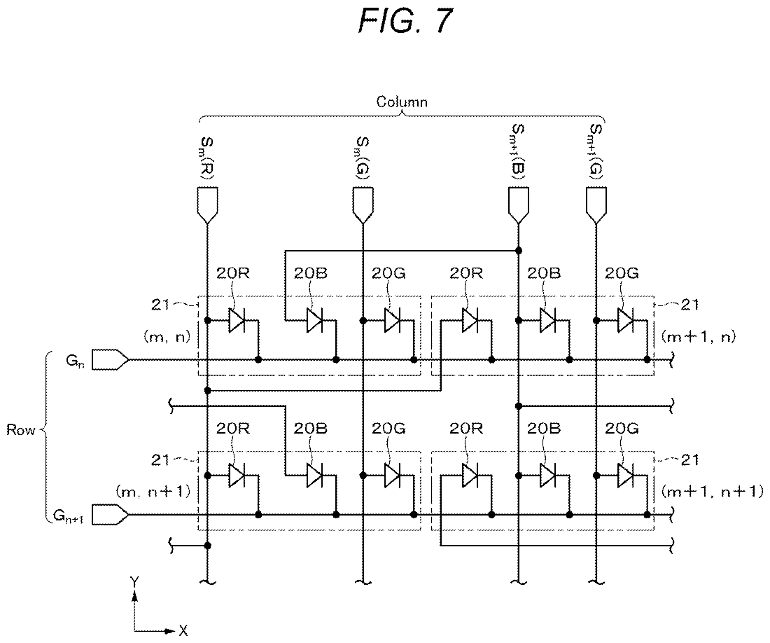

Although the example in which pairs of the pixels 21 sharing the signal line S(R) and the signal line S(B) are arranged in a line in the Y-axis direction (see FIGS. 1 and 2) has been described in the first embodiment, pairs of the pixels 21 sharing the signal line S(R) and the signal line S(B) may be arranged in a zigzag manner in the Y-axis direction as illustrated in FIGS. 6 and 7.

More specifically, pairs of the pixels 21 may have the following connection mode. The red LED elements 20R respectively included in the pixel 21 at the position (m, n) and the pixel 21 at the position (m+1, n) share one signal line Sₘ(R), which is similar to the first embodiment. Furthermore, the blue LED elements 20B respectively included in the pixel 21 at the position (m, n) and the pixel 21 at the position (m+1, n) also share one signal line Sₘ₊₁(B), which is similar to the first embodiment. On the other hand, the red LED elements 20R respectively included in the pixel 21 at the position (m+1, n+1) and the pixel 21 at a position (m+2, n+1) share one signal line Sₘ₊₂(R), which is different from the first embodiment. Furthermore, the blue LED elements 20B respectively included in the pixel 21 at the position (m+1, n+1) and the pixel 21 at the position (m+2, n+1) also share one signal line Sₘ₊₁(B), which is different from the first embodiment.

In FIG. 6, the broken-line frames R2 indicate pairs of the pixels 21 sharing the signal line Sₘ(R) and the signal line Sₘ₊₁(B), and pairs of the pixels 21 sharing the signal line signal lines Sₘ₊₂(R) and Sₘ₊₁(B).

### Modified Example 2

Although the example in which the red LED element 20R, the green LED element 20G, and the blue LED element 20B included in each of the pixels 21 are connected to the signal line S(R), the signal line S(G), and the signal line S(B), respectively, and all of the red LED element the green LED element 20G, and the blue LED element 20B included in each of the pixels 21 can be turned on has been described in the first embodiment, the configuration of the display device 10 is not limited thereto. For example, one of the red LED element 20R and the blue LED element 20B included in each of the pixels 21 may be configured not to be connected to the signal line S so as not to be turned on. In this case, the pixels 21 each including the red LED element 20R that is not turned on and the pixels 21 each including the blue LED element 20B that is not turned on may be alternately arranged in the X-axis direction and alternately arranged in the Y-axis direction.

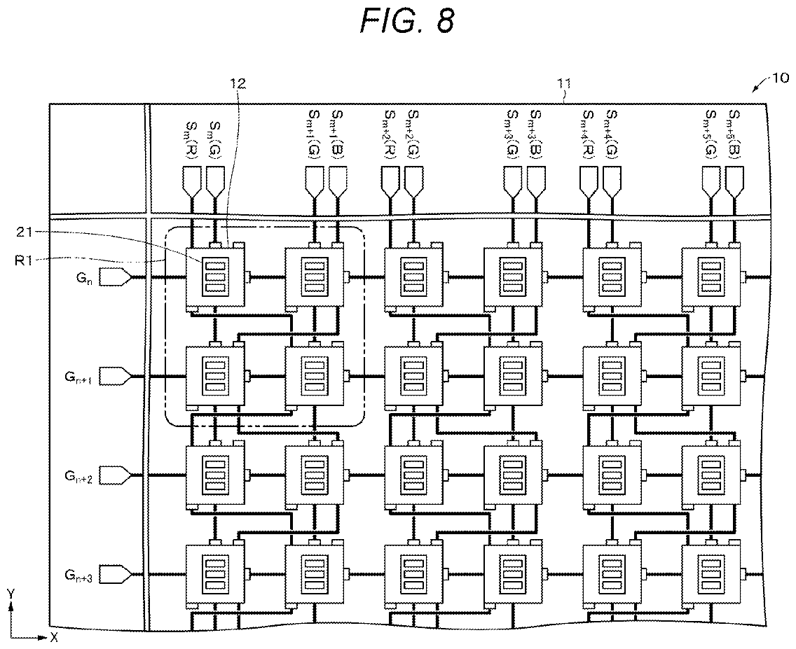

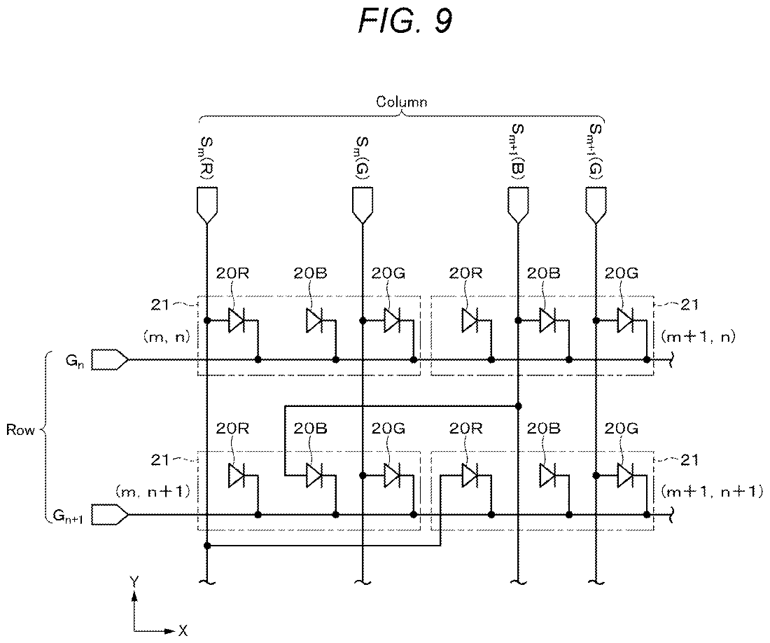

FIG. 8 is a plan view illustrating an example of a configuration of display device 10 according to a modified example. FIG. 9 is a diagram illustrating an example of a circuit of a portion illustrated in the region R1 of FIG. 8. In a case where it is assumed that two pixels 21 adjacent in the X-axis direction form a pair, an anode of the red LED element 20R included in one pixel 21 forming the pair is connected to the signal line S(R), whereas an anode of the red LED element 20R included in the other pixel 21 is not connected to the signal line S(R). Furthermore, an anode of the blue LED element 20B included in the one pixel 21 forming the pair is not connected to the signal line S(B), whereas an anode of the blue LED element 20B included in the other pixel 21 is connected to the signal line S(B). That is, the red LED elements 20R and the blue LED elements 20B included in two pixel columns adjacent in the X-axis direction are connected in a zigzag manner in the Y-axis direction by the signal lines S(R) and S(B), respectively.

### Modified Example 3

In the first embodiment, the description has been given regarding the example in which, in the case where two pixels 21 adjacent in the X-axis direction form a pair, the red LED elements 20R respectively included in the two pixels 21 forming the pair share one signal line S(R), and the blue LED elements 20B respectively included in the two pixels 21 forming the pair share one signal line S(B). However, the configuration of the display device 10 is not limited thereto.

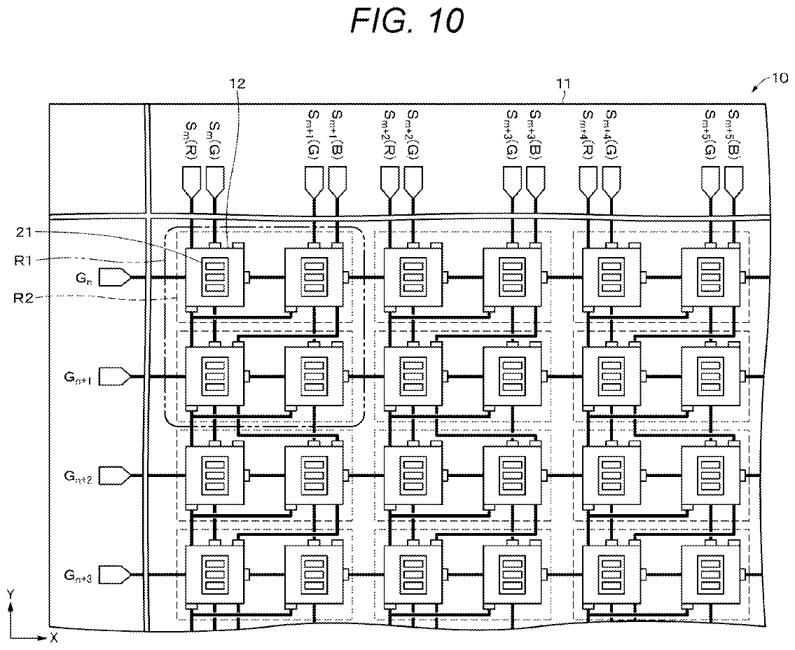

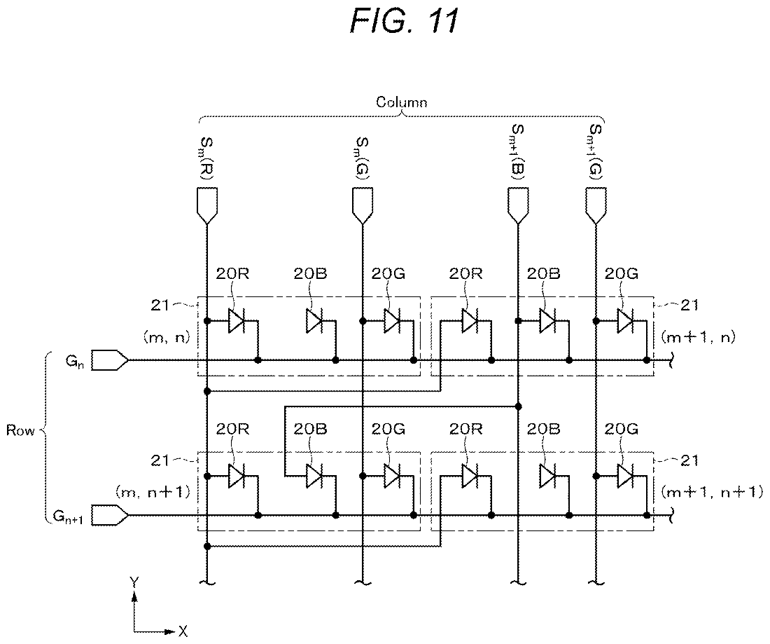

For example, as illustrated in FIGS. 10 and 11, in a case where it is assumed that two pixels 21 adjacent in the X-axis direction form a pair, the red LED elements 20R included in the two pixels 21 forming the pair share one signal line S(R). On the other hand, the blue LED elements 20B included in the two pixels 21 forming the pair do not share one signal line S(B). That is, the blue LED element 20B included in one of the two pixels 21 forming the pair is connected to the signal line S(B), whereas the blue LED element 20B included in the other pixel is not connected to the signal line S(B). The blue LED elements 20B included in two pixel columns adjacent in the X-axis direction are connected in a zigzag manner by the signal lines S(B).

More specifically, the red LED elements 20R respectively included in the pixel 21 at the position (m, n) and the pixel 21 at the position (m+1, n) share one signal line Sₘ(R). On the other hand, the blue LED elements 20B respectively included in the pixel 21 at the position (m, n) and the pixel 21 at the position (m+1, n) do not share one signal line Sₘ₊₁(B). That is, the blue LED element 20B included in the pixel 21 at the position (m, n) is not connected to the signal line Sₘ₊₁(B), whereas the blue LED element 20B included in the pixel 21 at the position (m+1, n) is connected to the signal line Sₘ₊₁(B).

The red LED elements 20R respectively included in the pixel 21 at the position (m, n+1) and the pixel 21 at the position (m+1, n+1) share one signal line Sₘ(R). On the other hand, the blue LED elements 20B respectively included in the pixel 21 at the position (m, n+1) and the pixel 21 at the position (m+1, n+1) do not share one signal line Sₘ₊₁(B). That is, the blue LED element 20B included in the pixel 21 at the position (m+1, n) is connected to the signal line Sₘ₊₁(B), whereas the blue LED element 20B included in the pixel 21 at the position (m+1, n+1) is not connected to the signal line Sₘ₊₁(B).

Note that the blue LED elements 20B included in the two pixels 21 forming a pair may share one signal line S(B) while the red LED elements 20R included in the two pixels 21 forming the pair do not share one signal line S(R).

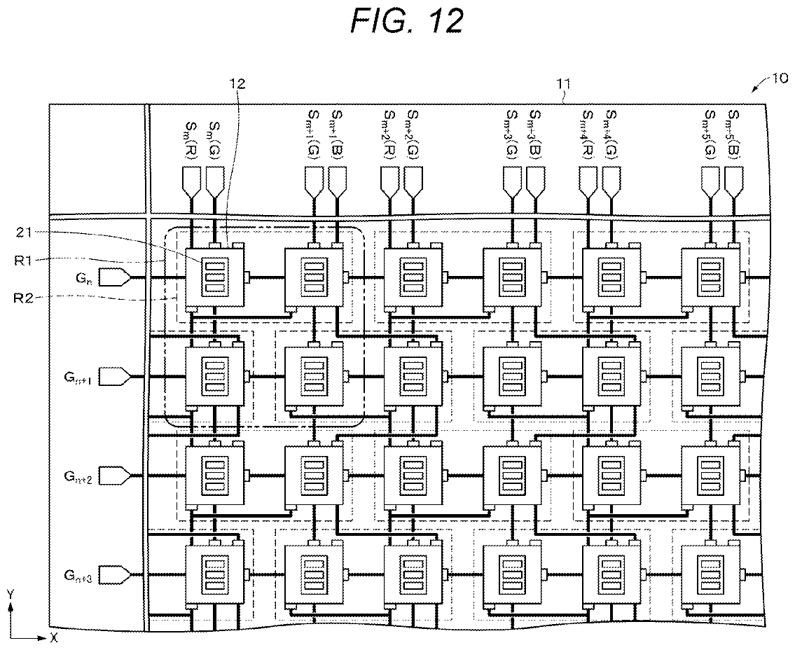

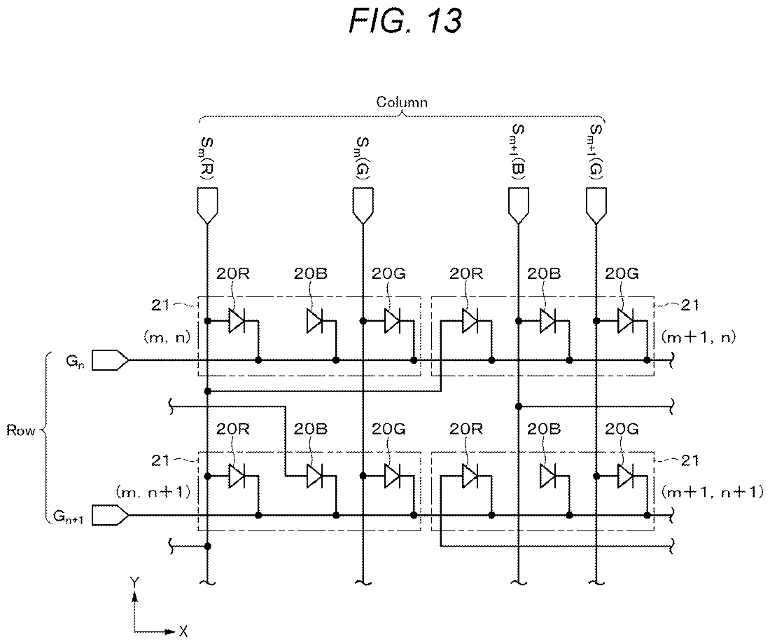

Although the above-described example in which pairs of the pixels 21 sharing the signal line S(R) are arranged in a line in the Y-axis direction has been described in the above example, pairs of the pixels 21 sharing the signal line S(R) may be arranged in a zigzag manner in the Y-axis direction as illustrated in FIGS. 12 and 13. In this case, more specifically, the respective pixels 21 may have the following connection mode.

The red LED elements 20R respectively included in the pixel 21 at the position (m, n) and the pixel 21 at the position (m+1, n) are similar to those of the above-described example. Furthermore, the blue LED elements 20B respectively included in the pixel 21 at the position (m, n) and the pixel 21 at the position (m+1, n) are also similar to those of the above-described example. On the other hand, the red LED elements 20R respectively included in the pixel 21 at the position (m+1, n+1) and the pixel 21 at the position (m+2, n+1) share one signal line Sₘ₊₂(R), which is different from the above-described example. Furthermore, the blue LED elements 20B respectively included in the pixel 21 at the position (m+1, n+1) and the pixel 21 at the position (m+2, n+1) have a connection mode from that of the above-described example. That is, the blue LED element 20B included in the pixel 21 at the position (m+1, n+1) is not connected to the signal line Sₘ₊₁(B), whereas the blue LED element 20B included in the pixel 21 at the position (m+2, n+1) is connected to the signal line Sₘ₊₁(B).

### Modified Example 4

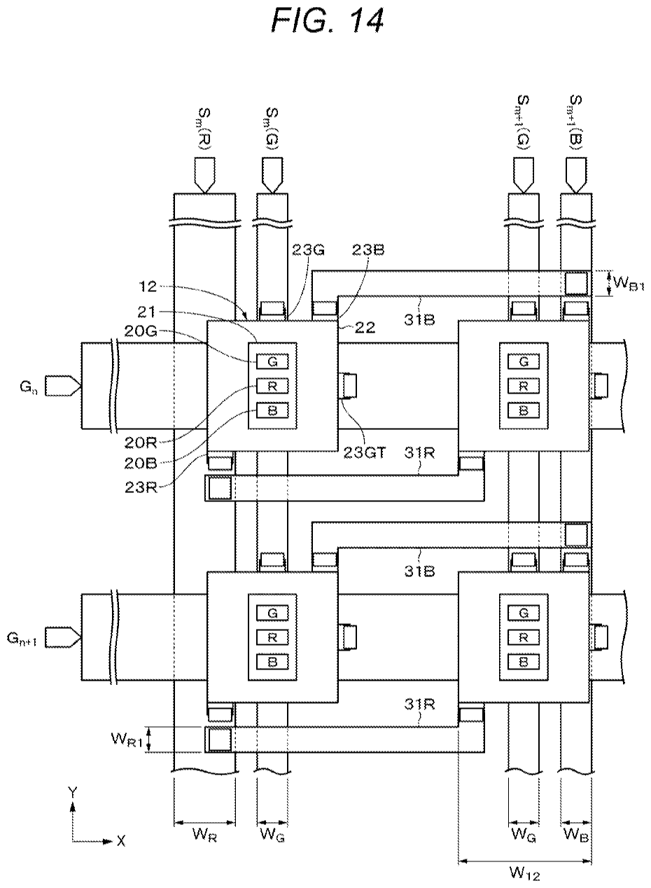

As illustrated in FIG. 14, a width W_{R} of the signal line S(R) may be wider than a width W_{B} of the signal line S(B) and a width W_{G} of the signal line S(G). A ratio (W_{R}/W_{G}) of the width W_{R} of the signal line S(R) connected to the red LED element 20R with respect to the width W_{G} of the signal line S(G) connected to the green LED element 20G is, for example, 1 or more and 3 or less, preferably 1.7 or more and 2.3 or less, and more preferably about 2. In general, in the LED display, a current ratio (Current flowing through signal line S(R):Current flowing through signal line S(G):Current flowing through signal line S(B)) among the signal line S(R), the signal line S(G), and the signal line S(B) for displaying white is about 1:1:0.5, and thus, the current ratio between the signal line S(R) and the signal line S(G) is 1:1. In the display device 10 according to the first embodiment, the number of the signal lines S(R) is half the number of signal lines S(G), and thus, the current flowing in one signal line S(R) is about twice the current flowing in one signal line S(G). The width W_{R} of the signal line S(R) is, for example, about 150 μm. The width W_{B} of the signal line S(B) and the width W_{G} of the signal line S(G) are, for example, about 75 μm.

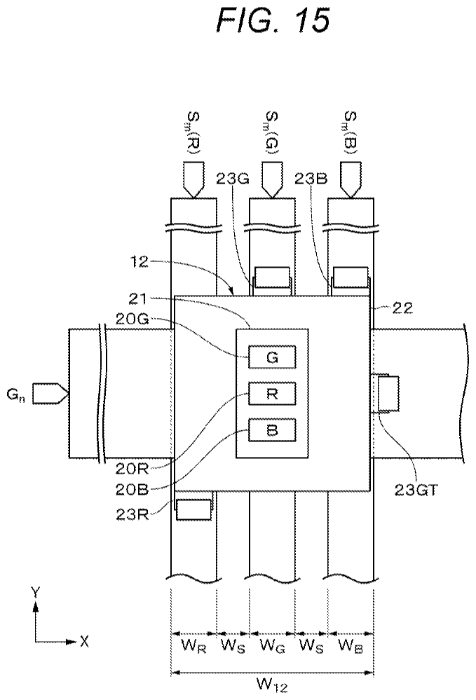

FIG. 15 is a plan view illustrating an example of the signal line S(R), the signal line S(B), and the signal line S(G) of the display device 110 (see FIG. 4) according to the comparative example. A width W_{R} of the signal line S(R), a width W_{B} of the signal line S(B), and a width W_{G} of the signal line S(G) are set to be the same. In the following description, the width W_{R} of the signal line S(R), the width W_{B} of the signal line S(B), and the width W_{G} of the signal line S(G) will be collectively referred to as widths W of the signal lines S.

A space is provided between the adjacent signal lines S. A width W_{S} of the space between the signal lines S is substantially equal to the width W (=W_{R}, W_{G}, W_{B}) of the signal line S. In a case where a dimension W₁₂ of an SMD 12 in the X-axis direction is about 350 μm, the width W of the signal line S and the width W_{S} of the space between the signal lines S are set to, for example, about 75 μm.

In the display device 10 according to the first embodiment, the two red LED elements 20R included in the two pixels 21 adjacent in the X-axis direction are connected in parallel. Similarly, the two blue LED elements 20B included in the two pixels 21 adjacent in the X-axis direction are also connected in parallel. Therefore, a current value flowing through the signal line S(R) of the display device 10 is about twice a current value flowing through the signal line S(R) of the display device 110. Similarly, a current value flowing through the signal line S(B) of the display device 10 is about twice a current value flowing through the signal line S(B) of the display device 110.

However, a light emission intensity of the blue LED element 20B can be lower than light emission intensities of the red LED element 20R and the green LED element 20G. Therefore, the current value flowing through the signal line S(B) can be set to about half current values flowing through the signal lines S(R) and S(G). Therefore, the width W_{B} of the signal line S(B) may be similar to the width W_{B} of the signal line S(B) of the display device 110. That is, the width W_{B} of the signal line S(B) may be substantially similar to the width W_{G} of the signal line S(G) of the display device 10. On the other hand, the width W_{R} of the signal line S(R) of the red LED element 20R is preferably about twice the width W_{R} of the signal line S(R) of the display device 110. That is, that is, the width W_{R} of the signal line S(R) of the red LED element 20R is preferably about twice the width W_{G} of the signal line S(G) of the display device 10.

The red LED element 20R included in one of the two pixels 21 adjacent in the X-axis direction may be connected to the signal line S(R) via a connection line 31R. In this case, a width W_{R1} of the connection line 31R may be about ½ of the width W_{R} of the signal line S(R). That is, the width W_{R1} of the connection line 31R may be substantially similar to the width W_{G} of the signal line S(G). The blue LED element 20B included in one of the two pixels 21 adjacent in the X-axis direction may be connected to the signal line S(B) via a connection line 31B. In this case, a width W_{B1} of the connection line 31B may be substantially similar to the width W_{B} of the signal line S(B).

### Modified Example 5

Although the example in which the SMD 12 includes the single pixel 21 has been described in the first embodiment, the number of pixels 21 included in the SMD 12 is not limited thereto, and the SMD 12 may include two or more pixels 21. Specifically, for example, the SMD 12 may include n×m pixels 21P (here, n and m are each independently, for example, an integer of 1 or more, preferably an integer of 2 or more, n is the number of pixels 21 in the X-axis direction, and m is the number of pixels 21 in the Y-axis direction).

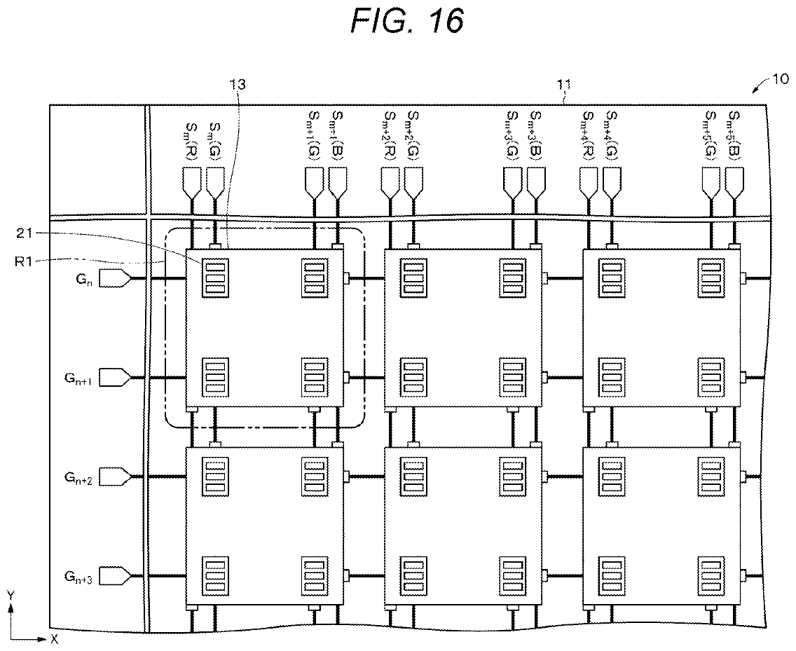

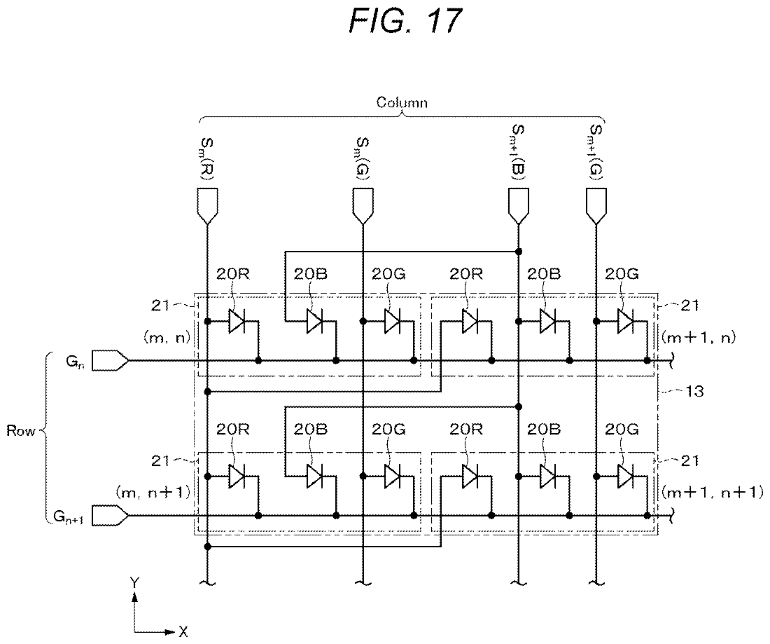

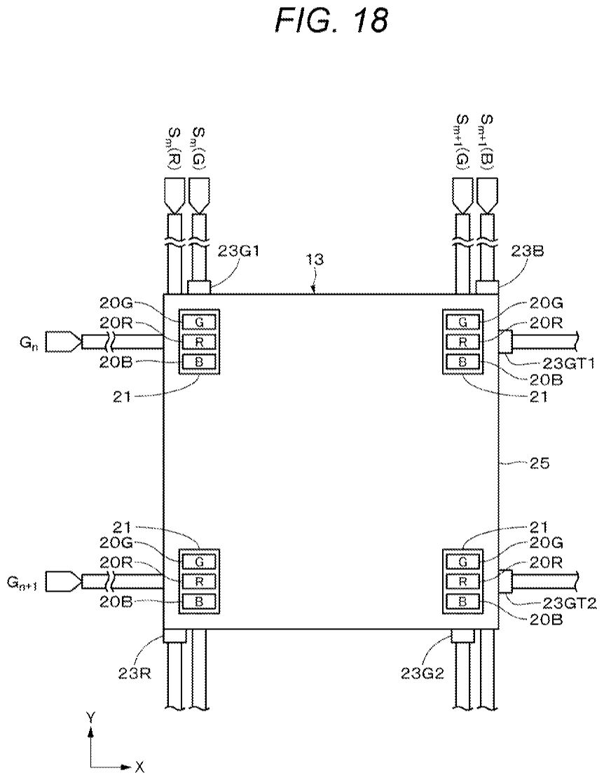

FIG. 16 is a plan view illustrating an example of a configuration of the display device 10 according to a modified example. FIG. 17 is a diagram illustrating an example of a circuit of a portion illustrated in the region R1 of FIG. 16. FIG. 18 is a plan view illustrating an example of a configuration of an SMD 13. The SMD 12 is an SMD (4 in 1 SMD) in which four pixels are integrated into one chip. The SMD 13 includes four pixels 21 and a package 25. The four pixels 21 of the SMD 12 are provided at positions (m, n), (m+1, n), (m, n+1), and (m+1, n+1), respectively.

The package 25 includes the anode terminal 23R, an anode terminal 23G1, an anode terminal 23G2, the anode terminal 23B, a cathode terminal (gate terminal) 23GT1, and a cathode terminal (gate terminal) 23GT2.

An anode of the red LED element 20R included in the pixel 21 at the position (m, n) is connected to the signal line Sₘ(R) via the anode terminal 23R. An anode of the green LED element 20G included in the pixel 21 at the position (m, n) is connected to the signal line Sₘ(G) via the anode terminal 23G1. An anode of the blue LED element 20B included in the pixel 21 at the position (m, n) is connected to the signal line Sₘ₊₁(B) via the anode terminal 23B. Cathodes of the red LED element 20R, the green LED element 20G, and the blue LED element included in the pixel 21 at the position (m, n) are connected to the scanning line Gₙ via the cathode terminal 23GT1.

An anode of the red LED element 20R included in the pixel 21 at the position (m+1, n) is connected to the signal line Sₘ(R) via the anode terminal 23R. An anode of the green LED element 20G included in the pixel 21 at the position (m+1, n) is connected to the signal line Sₘ₊₁(G) via the anode terminal 23G2. An anode of the blue LED element 20B included in the pixel 21 at the position (m+1, n) is connected to the signal line Sₘ₊₁(B) via the anode terminal 23B. Cathodes of the red LED element 20R, the green LED element 20G, and the blue LED element 20B included in the pixel 21 at the position (m+1, n) are connected to the scanning line Gₙ via the cathode terminal 23GT1.

A connection mode between each of the red LED element 20R, the green LED element and the blue LED element 20B included in the pixel 21 at the position (m, n+1) and each of the signal lines Sₘ(R), Sₘ(G), and Sₘ₊₁(B) is similar to that of the pixel 21 at the position (m, n). Cathodes of the red LED element 20R, the green LED element 20G, and the blue LED element included in the pixel 21 at the position (m, n+1) are connected to the scanning line Gₙ₊₁ via the cathode terminal 23GT2.

A connection mode between each of the red LED element 20R, the green LED element and the blue LED element 20B included in the pixel 21 at the position (m+1, n+1) and each of the signal lines Sₘ(R), Sₘ₊₁(G), and Sₘ₊₁(B) is similar to that of the pixel 21 at the position (m+1, n). Cathodes of the red LED element 20R, the green LED element 20G, and the blue LED element 20B included in the pixel 21 at the position (m+1, n+1) are connected to the scanning line Gₙ₊₁ via the cathode terminal 23GT2.

### Modified Example 6

Although the example in which the red light source, the green light source, and the blue light source are respectively the red LED element 20R, the green LED element 20G, and the blue LED element 20B has been described in the first embodiment described above, the red light source, the green light source, and the blue light source are not limited to this example.

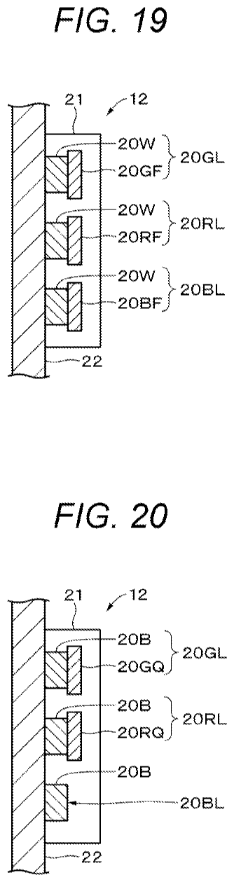

FIG. 19 is a cross-sectional view illustrating a first configuration example of a red light source 20RL, a green light source 20GL, and a blue light source 20BL included in the pixel 21. The red light source 20RL may include, instead of the red LED element 20R, a white LED element 20W and a red filter 20RF provided on the white LED element 20W. The white LED element 20W is configured to emit white light. The red filter 20RF absorbs light having a prescribed wavelength out of the white light emitted from the white LED element 20W and transmits the red light.

The green light source 20GL may include, instead of the green LED element 20G, the white LED element 20W and a green filter 20GF provided on the white LED element 20W. The green filter 20GF absorbs light having a prescribed wavelength out of the white light emitted from the white LED element 20W and transmits green light.

The blue light source 20BL may include, instead of the blue LED element 20B, the white LED element 20W and a blue filter 20BF provided on the white LED element 20W. The blue filter 20BF absorbs light having a prescribed wavelength out of white light emitted from the white LED element 20W and transmits blue light.

FIG. 20 is a cross-sectional view illustrating a second configuration example of the red light source 20RL, the green light source 20GL, and the blue light source 20BL included in the pixel 21. The red light source 20RL may include, instead of the red LED element 20R, the blue LED element 20B and a color conversion layer 20RQ provided on the blue LED element 20B. The color conversion layer 20RQ converts blue light emitted from the blue LED element 20B into red light. The color conversion layer 20RQ is, for example, a quantum dot (QD).

The green light source 20GL may include, instead of the green LED element 20G, the blue LED element 20B and a color conversion layer 20GQ provided on the blue LED element 20B. The color conversion layer 20GQ converts blue light emitted from the blue LED element 20B into green light. The color conversion layer 20GQ is, for example, a quantum dot.

The blue light source 20BL is the blue LED element 20B similarly to the first embodiment.

### 2 Second Embodiment

### [Configuration of Display Device]

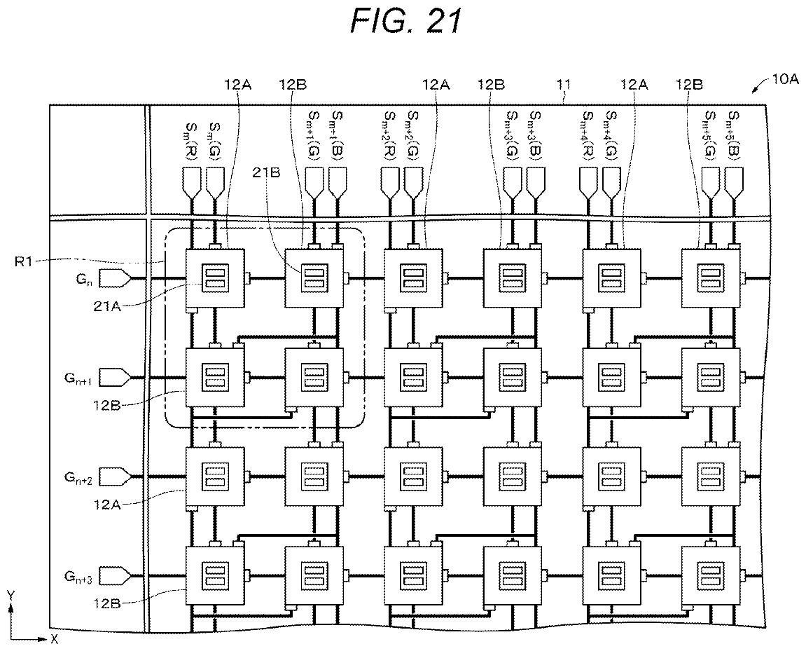

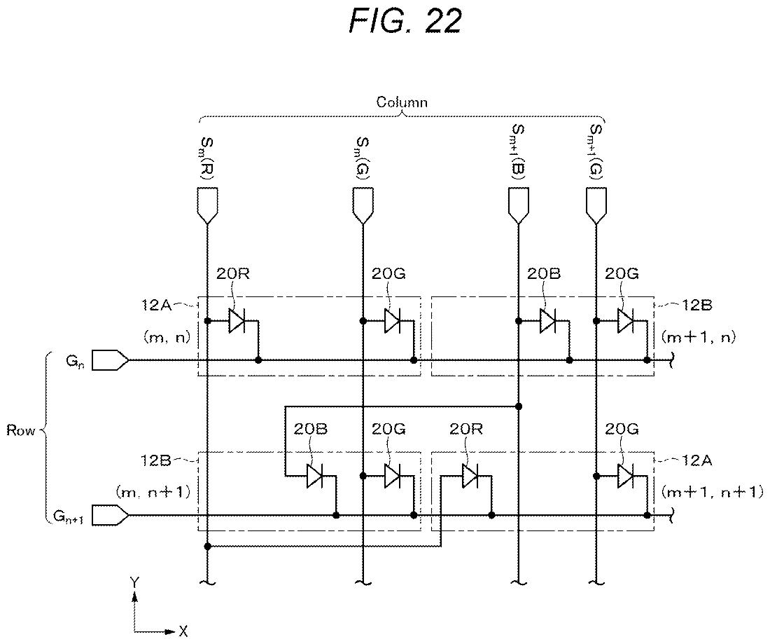

FIG. 21 is a plan view illustrating an example of a configuration of a display device 10A according to a second embodiment of the present disclosure. FIG. 22 is a plan view illustrating an example of a circuit of a portion indicated by the region R1 of FIG. 21. The display device 10A is different from the display device 10 according to the first embodiment in terms of including multiple SMDs 12A and multiple SMDs 12B arranged on the substrate 11. The SMDs 12A and 12B are alternately arranged in the X-axis direction (first direction) and alternately arranged in the Y-axis direction (second direction).

### (SMD)

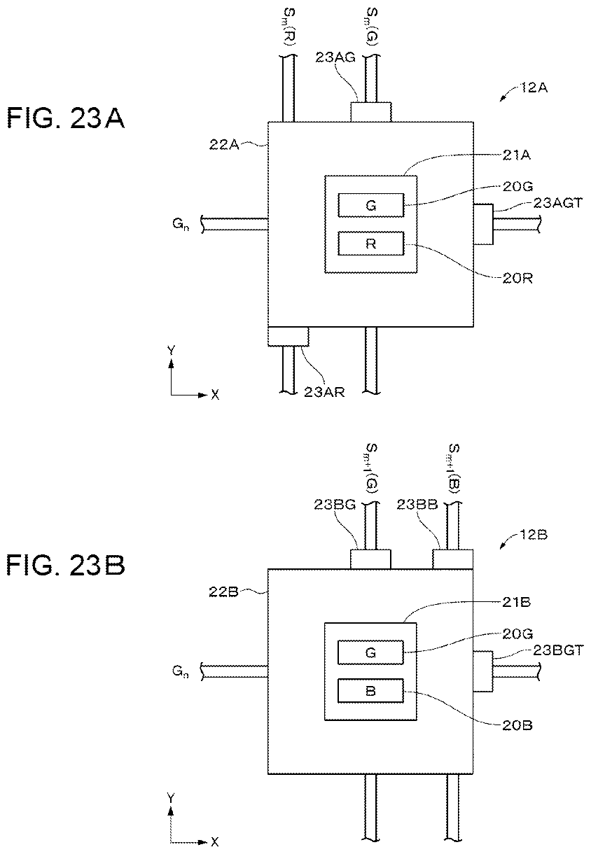

FIG. 23A is a plan view illustrating an example of a configuration of the SMD 12A. The SMD 12A is an SMD (1 in 1 SMD) in which one pixel is configured in one chip. The SMD 12A includes a pixel (third pixel) 21A and a package 22A. The pixel 21A includes the LED elements 20R and 20G of two colors. More specifically, the pixel 21A includes the red LED element 20R and the green LED element 20G.

The package 22A includes an anode terminal 23AR, an anode terminal 23AG, and a cathode terminal (gate terminal) 23AGT. The anode terminal 23AR is connected to the signal line S(R). The anode terminal 23AG is connected to the signal line S(G). The cathode terminal (gate terminal) 23AGT is connected to the scanning line G.

The SMD 12A is of a common cathode type having a common cathode terminal. An anode of the red LED element 20R is connected to the anode terminal 23AR. An anode of the green LED element 20G is connected to the anode terminal 23AG. Cathodes of the red LED element 20R and the green LED element 20G are connected to the cathode terminal 23AGT.

FIG. 23B is a plan view illustrating an example of a configuration of the SMD 12B. The SMD 12B is an SMD (1 in 1 SMD) in which one pixel is configured in one chip. The SMD 12B includes a pixel (fourth pixel) 21B and a package 22B. The pixel 21A includes the LED elements 20G and 20B of two colors. More specifically, the pixel 21B includes the green LED element 20G and the blue LED element 20B.

The package 22B includes an anode terminal 23BG, an anode terminal 23BB, and a cathode terminal (gate terminal) 23BGT. The anode terminal 23BG is connected to the signal line S(G). The anode terminal 23BB is connected to the signal line S(B). The cathode terminal (gate terminal) 23BGT is connected to the scanning line G.

The SMD 12B is of a common cathode type having a common cathode terminal. An anode of the green LED element 20G is connected to the anode terminal 23BG. An anode of the blue LED element 20B is connected to the anode terminal 23BB. Cathodes of the green LED element 20G and the blue LED element 20B are connected to the cathode terminal 23BGT.

The multiple pixels 21A and the multiple pixels 21B are arranged in a matrix. The pixels 21A and the pixels 21B are alternately arranged in the X-axis direction and alternately arranged in the Y-axis direction.

### [Connection Between LED Element and Each of Signal Line and Scanning Line]

The number of signal lines S(G) is one per pixel column. The number of signal lines columns. Therefore, the number of signal lines S is two per pixel column.

In a case where it is assumed that two adjacent pixel columns form a pair, the red LED elements 20R included in the respective pixels 21A forming the two pixel columns share one signal line S(R). Furthermore, the blue LED elements 20B included in the respective pixels 21B forming the two pixel columns share one signal line S(B).

In a case where it is assumed that two pixels 21B adjacent in an oblique direction (direction between the X-axis direction and the Y-axis direction) in two adjacent pixel columns form a pair, the blue LED elements 20B included in the pixels 21B forming the pair share one signal line S(B). Similarly, in a case where it is assumed that two pixels 21A adjacent in the oblique direction in two adjacent pixel columns form a pair, the red LED elements 20R included in the pixels 21A forming the pair share one signal line S(R).

More specifically, the blue LED element 20B included in the pixel 21 at a position (n, m+1) and the pixel 21B at a position (n+1, m) share one signal line Sₘ₊₁(B). The red LED element 20R included in the pixel 21A at a position (n, m) and the pixel 21A at a position (n+1, m+1) share one signal line Sₘ(R).

The anode of the red LED element 20R included in the pixel 21A at a position (m, n) is connected to the signal line Sₘ(R) via the anode terminal 23AR. The anode of the green LED element 20G included in the pixel 21A at the position (m, n) is connected to the signal line Sₘ(G) via the anode terminal 23AG. The cathodes of the red LED element 20R and the green LED element 20G included in the pixel 21A at the position (m, n) are connected to the scanning line Gₙ via the cathode terminal 23AGT.

The anode of the green LED element 20G included in the pixel 21B at a position (m+1, n) is connected to the signal line Sₘ₊₁(G) via the anode terminal 23AG. The anode of the blue LED element 20B included in the pixel 21A at the position (m+1, n) is connected to the signal line Sₘ₊₁(B) via the anode terminal 23BB. The cathodes of the green LED element 20G and the blue LED element 20B included in the pixel 21B at the position (m+1, n) are connected to the scanning line Gₙ via the cathode terminal 23BGT.

The anode of the green LED element 20G included in the pixel 21B at a position (m, n+1) is connected to the signal line Sₘ(G) via the anode terminal 23BG. The anode of the blue LED element 20B included in the pixel 21B at the position (m, n+1) is connected to the signal line Sₘ₊₁(B) via the anode terminal 23BB. The cathodes of the green LED element 20G and the blue LED element 20B included in the pixel 21B at the position (m, n+1) are connected to the scanning line Gₙ₊₁ via the cathode terminal 23BGT.

The anode of the red LED element 20R included in the pixel 21A at a position (m+1, n+1) is connected to the signal line Sₘ(R) via the anode terminal 23AR. The anode of the green LED element 20G included in the pixel 21A at the position (m+1, n+1) is connected to the signal line Sₘ₊₁(G) via the anode terminal 23AG. The cathodes of the red LED element 20R and the green LED element 20G included in the pixel 21A at the position (m+1, n+1) are connected to the scanning line Gₙ₊₁ via the cathode terminal 23AGT.

The red LED element 20R included in the pixel 21A at the position (m, n) and the red LED element 20R included in the pixel 21A at the position (m+1, n+1) are connected in series. The blue LED element 20B included in the pixel 21B at the position (m+1, n) and the blue LED element 20B included in the pixel 21B at the position (m, n+1) are connected in series.

### [Functions and Effects]

In the display device 10A according to the second embodiment, the number of the signal lines S is two per pixel column as illustrated in FIGS. 21 and 22. Therefore, the similar functions and effects as those of the display device 10 according to the first embodiment can be obtained.

In the display device 10 according to the first embodiment, the pixel 21 includes the LED elements 20R, 20G, and 20B of the three colors as illustrated in FIG. 3. On the other hand, in the display device 10A according to the second embodiment, the pixel 21A includes the LED elements 20R and 20G of the two colors, and the pixel 21B includes the LED elements 20G and 20R of the two colors as illustrated in FIGS. 23A and 23B. Therefore, in the display device 10A according to the second embodiment, the total number of used LED elements 20 can be reduced as compared with the display device 10 according to the first embodiment.

### 3 Third Embodiment

### [Configuration of Display Device]

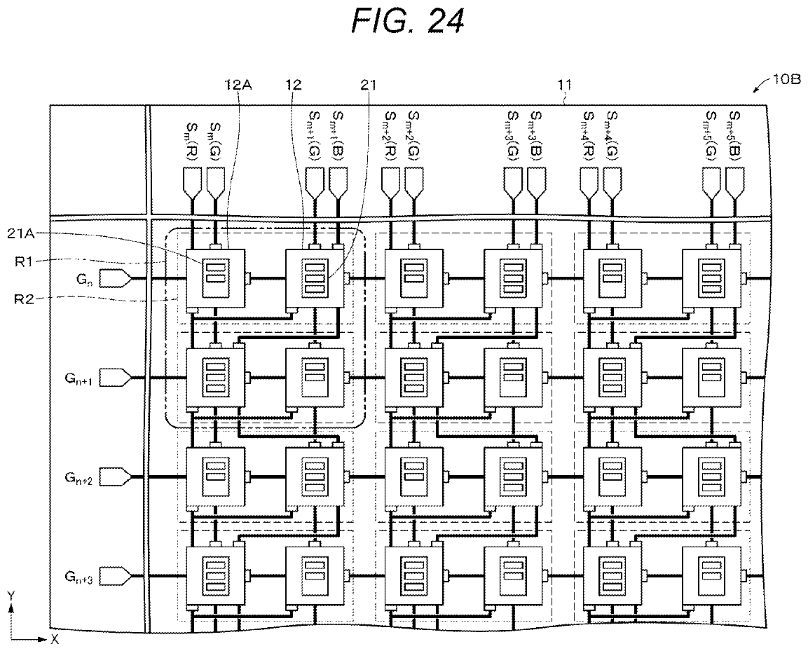

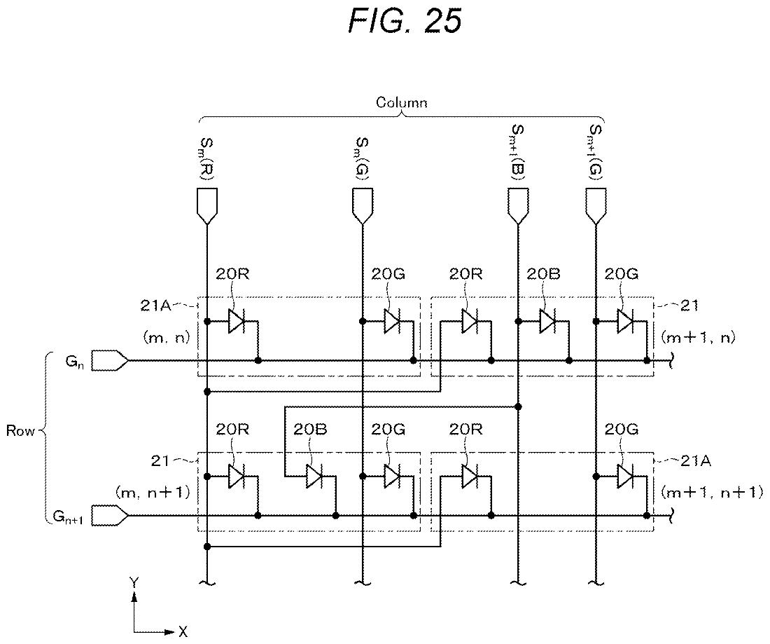

FIG. 24 is a plan view illustrating an example of a configuration of a display device 10B according to a third embodiment of the present disclosure. FIG. 25 is a plan view illustrating an example of a circuit of a portion indicated by the region R1 of FIG. 24. The display device 10B is different from the display device 10 according to the first embodiment in terms of including the multiple SMDs 12A and the multiple SMDs 12 arranged on the substrate 11.

The SMDs 12A and 12 are alternately arranged in the X-axis direction and alternately arranged in the Y-axis direction. The SMD 12A has a configuration as described in the second embodiment. The SMD 12 has a configuration as described in the second embodiment.

The multiple pixels 21A and the multiple pixels 21 are arranged in a matrix. The pixels 21A and the pixels 21 are alternately arranged in the X-axis direction and alternately arranged in the Y-axis direction.

### [Connection Between LED Element and Each of Signal Line and Scanning Line]

The number of signal lines S(G) is one per pixel column. The number of signal lines S(R) is one per two pixel columns. The number of signal lines S(B) is one per two pixel columns. Therefore, the number of signal lines S is two per pixel column.

In a case where it is assumed that two adjacent pixel columns form a pair, the red LED elements 20R included in the respective pixels 21A and 21 forming the two pixel columns share one signal line S(R). Furthermore, the blue LED elements 20B included in the respective pixels 21 forming the two pixel columns share one signal line S(B).

In a case where it is assumed that two pixels 21 and 21A adjacent in the X-axis direction form a pair, the red LED elements 20R respectively included in the two pixels 21 and 21A forming the pair share one signal line S(R).

In a case where it is assumed that two pixels 21 adjacent in an oblique direction (direction between the X-axis direction and the Y-axis direction) in two adjacent pixel columns form a pair, the blue LED elements 20B included in the two pixels 21 forming the pair share one signal line S(B).

The anode of the red LED element 20R included in the pixel 21A at a position (m, n) is connected to the signal line Sₘ(R) via the anode terminal 23AR. The anode of the green LED element 20G included in the pixel 21A at the position (m, n) is connected to the signal line Sₘ(G) via the anode terminal 23AG. The cathodes of the red LED element 20R and the green LED element 20G included in the pixel 21A at the position (m, n) are connected to the scanning line Gₙ via the cathode terminal 23AGT.

An anode of the red LED element 20R included in the pixel 21 at the position (m+1, n) is connected to the signal line Sₘ(R) via the anode terminal 23R. An anode of the green LED element 20G included in the pixel 21A at a position (m+1, n) is connected to the signal line Sₘ₊₁(G) via the anode terminal 23G. An anode of the blue LED element 20B included in the pixel 21 at the position (m+1, n) is connected to the signal line Sₘ₊₁(B) via the anode terminal 23B. Cathodes of the red LED element 20R, the green LED element 20G, and the blue LED element 20B included in the pixel 21A at the position (m+1, n) are connected to the scanning line Gₙ via the cathode terminal 23GT.

An anode of the red LED element 20R included in the pixel 21 at a position (m, n+1) is connected to the signal line Sₘ(R) via the anode terminal 23R. An anode of the green LED element 20G included in the pixel 21A at a position (m, n+1) is connected to the signal line Sₘ(G) via the anode terminal 23G. An anode of the blue LED element 20B included in the pixel 21 at the position (m, n+1) is connected to the signal line Sₘ₊₁(B) via the anode terminal 23B. Cathodes of the red LED element 20R, the green LED element 20G, and the blue LED element 20B included in the pixel 21A at the position (m, n+1) are connected to the scanning line Gₙ₊₁ via the cathode terminal 23GT.

The anode of the red LED element 20R included in the pixel 21A at a position (m+1, n+1) is connected to the signal line Sₘ(R) via the anode terminal 23AR. The anode of the green LED element 20G included in the pixel 21A at the position (m+1, n+1) is connected to the signal line Sₘ₊₁(G) via the anode terminal 23AG. The cathodes of the red LED element 20R and the green LED element 20G included in the pixel 21A at the position (m+1, n+1) are connected to the scanning line Gₙ₊₁ via the cathode terminal 23AGT.

The red LED element 20R included in a pixel 21A at the position (m, n) and the red LED element 20R included in the pixel 21 at the position (m+1, n) are connected in parallel. The red LED element 20R included in the pixel 21 at the position (m, n+1) and the red LED element 20R included in the pixel 21A at the position (m+1, n+1) are connected in parallel.

The blue LED element 20B included in the pixel 21 at the position (m+1, n) and the blue LED element 20B included in the pixel 21 at the position (m, n+1) are connected in series.

### [Functions and Effects]

In the display device 10B according to the second embodiment, the number of the signal lines S is two per pixel column as illustrated in FIGS. 24 and 25. Therefore, the similar functions and effects as those of the display device 10 according to the first embodiment can be obtained.

In the display device 10 according to the first embodiment, the pixel 21 includes the LED elements 20R, 20G, and 20B of the three colors as illustrated in FIG. 3. On the other hand, in the display device 10B according to the third embodiment, the pixel 21A includes the LED elements 20R and 20G of the two colors, and the pixel 21 includes the LED elements 20R, 20G, and 20B of the three colors as illustrated in FIGS. 24 and 25. Therefore, in the display device 10B according to the second embodiment, the total number of used LED elements 20 can be reduced as compared with the display device 10 according to the first embodiment.

### Modified Examples

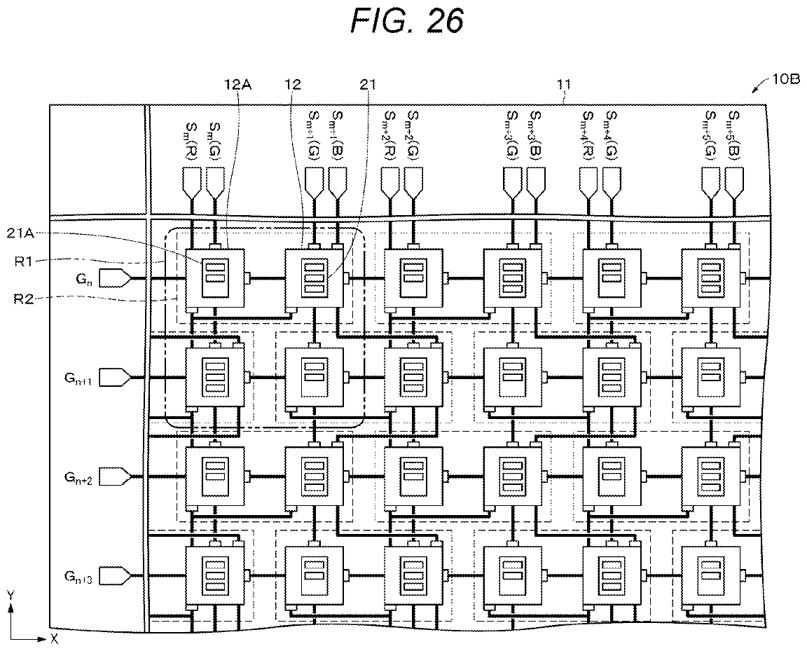

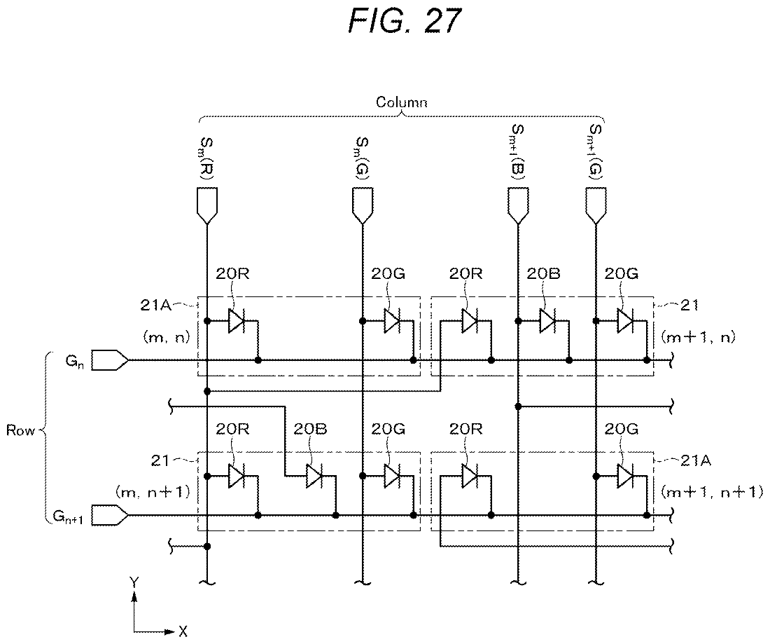

Although the example (see FIGS. 24 and 25) in which pairs of the pixels 21A and 21 sharing the signal line S(R) are arranged in a line in the Y-axis direction (extending direction of columns) has been described, the pairs of pixels 21A and 21 sharing the signal line S(R) may be arranged in a zigzag manner in the Y-axis direction as illustrated in FIGS. 26 and 27.

More specifically, pairs of the pixels 21 may have the following connection mode. The red LED elements 20R respectively included in the pixel 21A at the position (m, n) and the pixel 21 at the position (m+1, n) share one signal line Sₘ(R), which is similar to the third embodiment. The red LED element 20R respectively included in the pixel 21 at the position (m+1, n+1) and the pixel 21 at the position (m+2, n+1) share one signal line Sₘ₊₂(R), which is different from the third embodiment.

### 4 Fourth Embodiment

### [Configuration of Display Device]

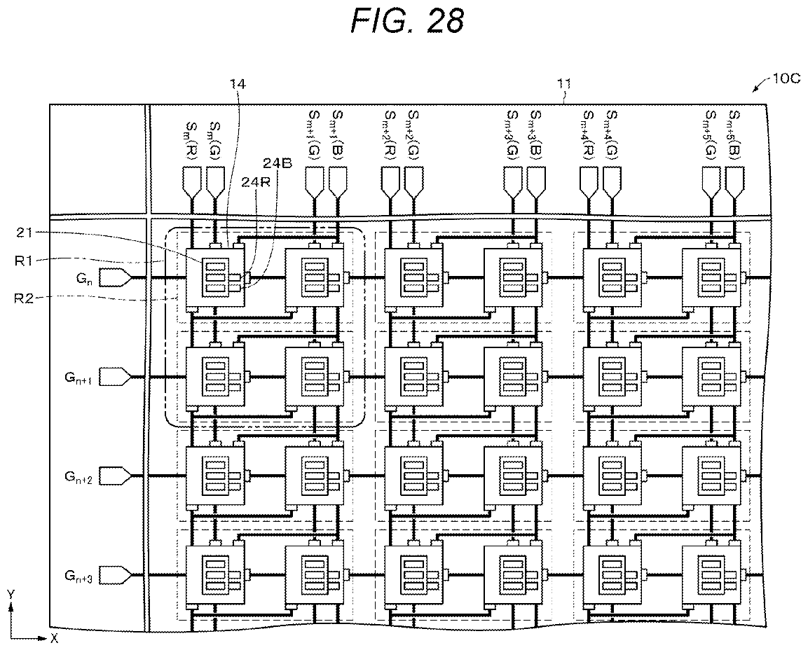

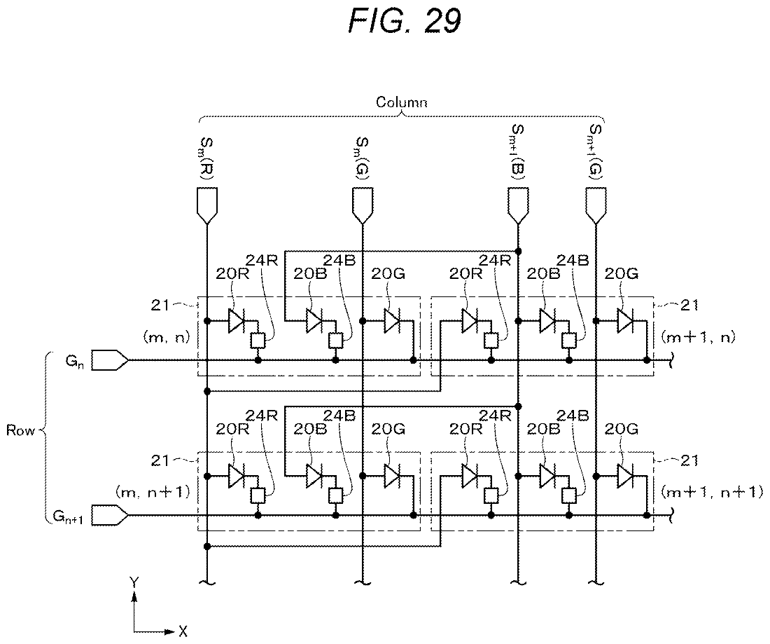

FIG. 28 is a plan view illustrating an example of a configuration of a display device 10C according to a fourth embodiment of the present disclosure. FIG. 29 is a plan view illustrating an example of a circuit of a portion indicated by the region R1 of FIG. 28. The display device 10C is different from the display device 10 according to the first embodiment in terms of including multiple SMDs 14 instead of multiple SMDs 12 (see FIG. 1).

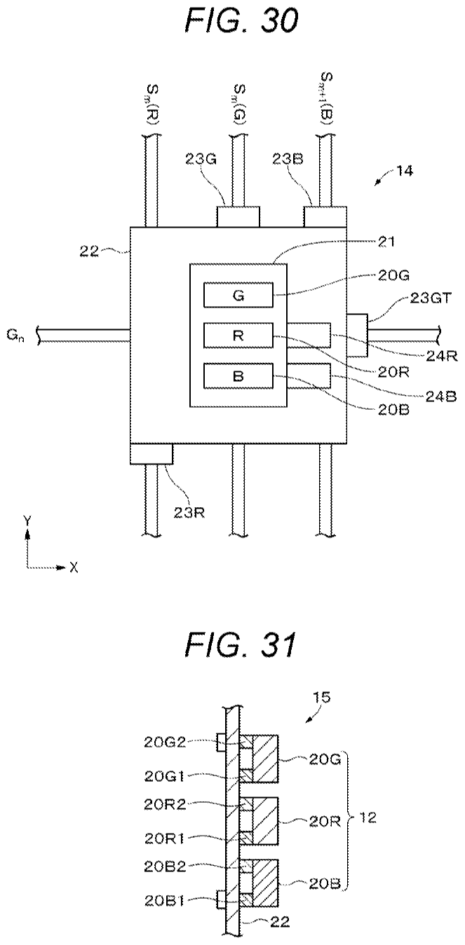

FIG. 30 is a plan view illustrating an example of a configuration of the SMD 14. The SMD 14 is different from the SMD 12 in the first embodiment in terms of including a resistance element 24R and a resistance element 24B. The resistance element (first resistor) 24R and the resistance element (second resistor) 24B are provided in the package 22 (see FIG. 3).

The resistance element 24R and the resistance element 24B are inserted into a common end of the pixels 21 driven in parallel. That is, the resistance element 24R and the resistance element 24B are connected in series to the red LED element 20R and the blue LED element 20B other than the green LED element 20G having the highest luminance among the LED elements 20R, 20G, and 20B of the three colors. More specifically, the resistance element 24R is provided between a cathode of the red LED element 20R and the cathode terminal GT. The resistance element 24B is provided between a cathode of the blue LED element 20B and the cathode terminal GT.

It is preferable that a resistance value of the resistance element 24R and a resistance value of the resistance element 24B be each independently in a range of 0.1 V/(LED current value [A]) Ω or more and 0.3 V/(LED current value [A]) Ω or less. The resistance element 24R and the resistance element 24B are generally called current feedback resistors and are provided to stabilize the current, and are preferably approximately four times or more and twelve times or less a built-in potential Vt (0.026 V) of a diode (including the light emitting diode LED). Therefore, it is preferable that each of the resistance values of the resistance element 24R and the resistance element 24B be selected in the above-described range. The LED current value [A] is, for example, 0.0001 A or more and 0.0500 A or less. For example, in a case where the LED current value is 0.001 A, the resistance value of the resistance element 24R and the resistance value of the resistance element 24B are each independently preferably in the range of 100Ω or more and 300Ω or less.

### [Functions and Effects]

Hereinafter, functions and effects will be described by comparing the display device 10C according to the fourth embodiment with the display device 10 according to the first embodiment.

In the display device 10 according to the first embodiment, the red LED elements 20R included in the two pixels 21 forming a pair share one signal line S(R), and thus, these red LED elements 20R are driven in parallel. Furthermore, the blue LED elements 20B included in the two pixels 21 forming a pair share one signal line S(B), and thus, these blue LED elements 20B are driven in parallel.

However, in the display device 10 according to the first embodiment, there is a possibility that variations in luminance between the red LED element 20R and the blue LED element 20B occur due to variations in current between the red LED element 20R and the blue LED element 20B driven in parallel. Because of the parallel driving, it is difficult to correct each of them by adjustment. As a method for solving such a problem, it is conceivable to select and use multiple red LED elements 20R and multiple blue LED elements 20B having small variations in characteristics. However, there is a possibility that the selection takes a lot of time and effort.

In the display device 10C according to the fourth embodiment, the SMD 14 includes the resistance element 24R and the resistance element 24B, and the resistance element 24R and the resistance element 24B are connected in series to the cathode sides of the red LED element 20R and the blue LED element 20B, respectively. Therefore, it is possible to reduce variations in current between the red LED element 20R and the blue LED element 20B driven in parallel. Therefore, it is possible to suppress variations in luminance between the red LED element 20R and the blue LED element 20B without taking time and effort to select the red LED element 20R and the blue LED element 20B.

### MODIFIED EXAMPLES

### Modified Example 1

Although an example in which the SMD 14 includes the resistance element 24R and the resistance element 24B in order to suppress variations in luminance has been described in the fourth embodiment, a resistor configured to suppress variations in luminance is not limited to this example. For example, variations in luminance may be suppressed by a contact resistance between the SMD 14 and the package 22.

FIG. 31 is a cross-sectional view illustrating an example of a configuration of an SMD 15. An anode and a cathode of the red LED element 20R are connected to the package 22 via joint portions 20R1 and 20R2, respectively. An anode and a cathode of the green LED element are connected to the package 22 via joint portions 20G1 and 20G2, respectively. An anode and a cathode of the blue LED element 20B are connected to the package 22 via joint portions 20B1 and 20B2, respectively.

A contact resistance (hereinafter, referred to as “first contact resistance”) of the joint portion 20R2 between the cathode of the red LED element 20R and the package 22 and a contact resistance (hereinafter, referred to as “second contact resistance”) of the joint portion 20B2 between the cathode of the blue LED element 20B and the package 22 are adjusted so as to suppress variations in luminance between the red LED element 20R and the red LED element 20R. It is preferable that a resistance value of the first contact resistance and a resistance value of the first contact resistance be each independently in a range of 0.1 V/(LED current value A) Ω or more and 0.3 V/(LED current value A) Ω or less. The first contact resistance and the second contact resistance may be set to be higher than a contact resistance of the joint portion 20G2 between the cathode of the green LED element 20G and the package 22.

### Modified Example 2

Although the example in which the SMD 15 includes the single pixel 21 has been described in the fourth embodiment, the number of pixels 21 included in the SMD is not limited thereto, and the SMD may include two or more pixels 21.

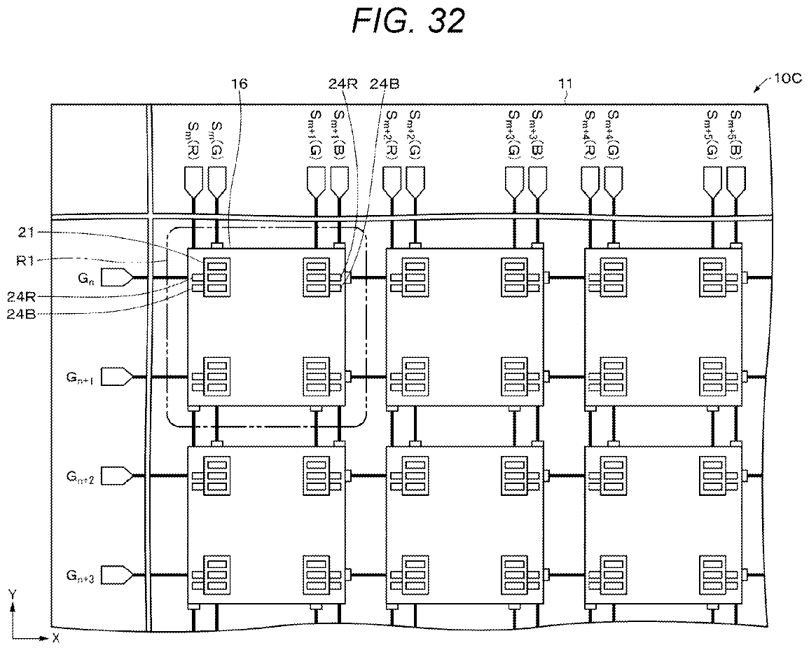

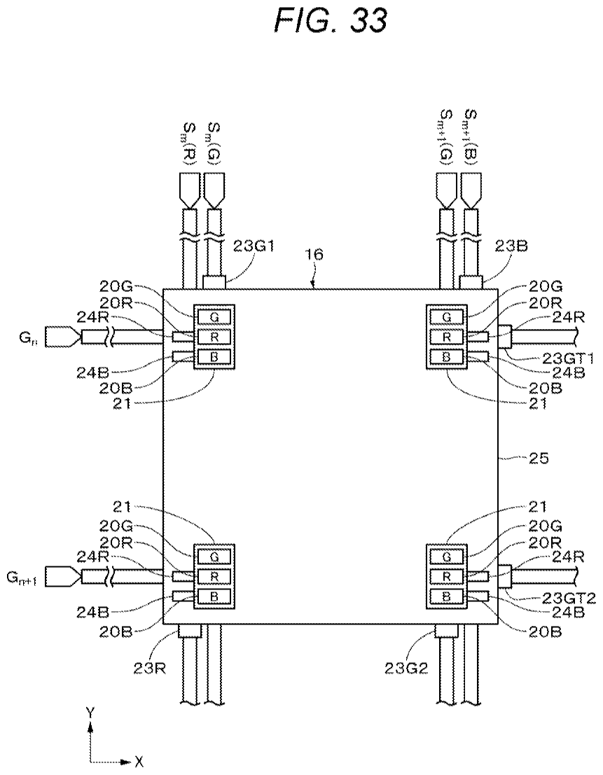

For example, as illustrated in FIGS. 32 and 33, an SMD 16 may include four pixels 21. In this case, the SMD 16 includes four resistance elements 24R and four resistance elements 24B.

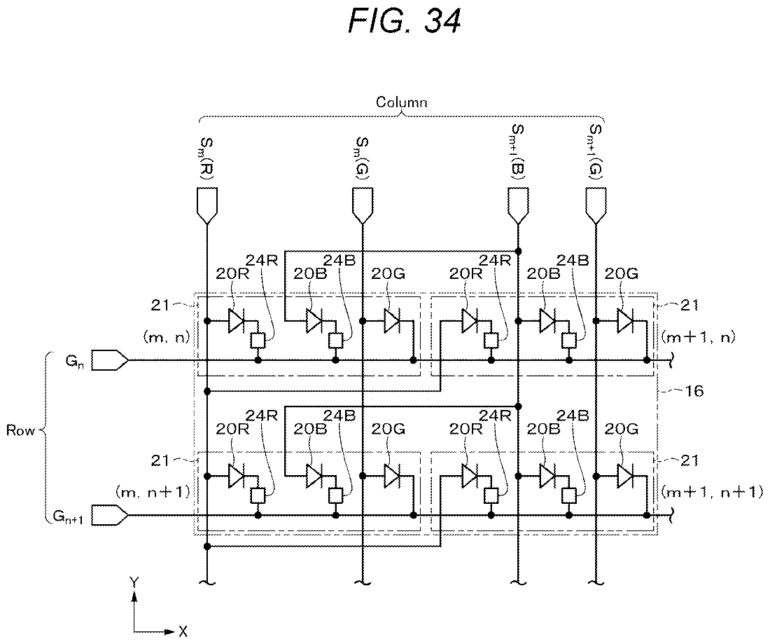

As illustrated in FIG. 34, the resistance element 24R is connected to a cathode of the red LED element 20R included in each of the pixels 21. The resistance element 24B is connected to a cathode of the blue LED element 20B included in each of the pixels 21.

### Modified Example 3

Although the examples in which the present disclosure is applied to the display device 10, 10 A, 10B, or 10C including the multiple SMDs 12, 12A, 12B, 13, 14, or 15 have been described in the first to fourth embodiments, the present disclosure is not limited thereto. For example, the present disclosure may be applied to a display device (chip on board (COB) display device) in which the multiple pixels 21, 21A, and 21B are directly arranged on the substrate 11.

### Modified Example 4

In the first to fourth embodiments, the display devices 10, 10 A, 10B, and 10C may be Glue On Board (GOB) display devices. That is, the display devices 10, 10A, 10B, and 10C may further include a protective layer that covers the multiple pixels 21, 21A, and 21B on the substrate 11. In this case, the protective layer is formed using, for example, a resin layer or a film.

### Modified Example 5

Although the example in which the connection mode of the LED elements 20 is the common cathode type has been described in the first to fourth embodiments, the connection mode of the LED elements 20 may be a common anode type.

Although the first to fourth embodiments and their modified examples of the present disclosure have been specifically described above, the present disclosure is not limited to the first to fourth embodiments and their modified examples described above, and various modifications based on the technical idea of the present disclosure can be made.

For example, the configurations, methods, shapes, numerical values, and the like described in the first to fourth embodiments and the modified examples thereof described above are merely examples, and different configurations, methods, shapes, numerical values, and the like may be used as necessary.

The configurations, methods, shapes, and the like of the first to fourth embodiments and the modified examples thereof described above can be combined with each other without departing from the gist of the present disclosure.

Furthermore, the present disclosure can also adopt the following configurations.
(1)
A display device including:
a substrate;
multiple pixels that are provided on the substrate and form multiple columns; and
multiple signal lines that are provided on the substrate and extend in a column direction,
in which the multiple pixels include at least one of multiple first pixels having light emitting diode elements of three colors or multiple second pixels having light emitting diode elements of two colors, and
a number of the signal lines is two per column.
(2)
The display device according to (1), in which
the multiple pixels include the multiple first pixels, and
the first pixel includes a light emitting diode element of a first color, a light emitting diode element of a second color, and a light emitting diode element of a third color.
(3)
The display device according to (1), in which
the multiple pixels include the multiple second pixels,
the multiple second pixels are arranged in a matrix,
the multiple second pixels include multiple third pixels and multiple fourth pixels,
the third pixel includes a light emitting diode element of a first color and a light emitting diode element of a second color,
the fourth pixel includes a light emitting diode element of the second color and a light emitting diode element of a third color, and
the third pixels and the fourth pixels are alternately arranged in the column direction and alternately arranged in a row direction.
(4)
The display device according to (1), in which
the multiple pixels include the multiple first pixels and the multiple second pixels,
the multiple pixels are arranged in a matrix,
the first pixel includes a light emitting diode element of a first color, a light emitting diode element of a second color, and a light emitting diode element of a third color,
the second pixel includes a light emitting diode element of the first color and a light emitting diode element of the second color, and
the first pixels and the second pixels are alternately arranged in the column direction and alternately arranged in a row direction.
(5)
The display device according to any one of (2) to (4), in which
the light emitting diode element of the first color is a red light emitting diode element,
the light emitting diode element of the second color is a green light emitting diode element, and
the light emitting diode element of the third color is a blue light emitting diode element.
(6)
The display device according to (2), in which the light emitting diode element of the second color has a highest luminance among the light emitting diode element of the first color, the light emitting diode element of the second color, and the light emitting diode element of the third color in a case where white display is performed.
(7)
The display device according to (6), in which
the multiple signal lines include:
multiple first signal lines connected to the light emitting diode elements of the first color;
multiple second signal lines connected to the light emitting diode elements of the second color; and
multiple third signal lines connected to the light emitting diode elements of the third color,
a number of the first signal lines is one per column,
a number of the second signal lines is one per two columns, and
a number of the third signal lines is one per two columns.
(8)
The display device according to (7), in which first pairs each including the first signal line and the second signal line and second pairs each including the second signal line and the third signal line are alternately arranged in a row direction.
(9)
The display device according to (7) or (8), in which
the light emitting diode elements of the first color respectively included in two pixels, adjacent in a row direction, share one of the first signal lines, and
the light emitting diode elements of the third color respectively included in the two pixels share one of the third signal lines.
(10)
The display device according to (7), in which
the light emitting diode element of the first color included in one pixel of two pixels, adjacent in a row direction, is connected to the first signal line, whereas the light emitting diode element of the first color included in another pixel of the two pixels is not connected to the first signal line, and
the light emitting diode element of the third color included in the one pixel of the two pixels is not connected to the third signal line, whereas the light emitting diode element of the third color included in the another pixel of the two pixels is connected to the third signal line.
(11)
The display device according to (10), in which
the multiple pixels are arranged in a matrix, and
the light emitting diode elements of the first color and the light emitting diode elements of the third color included in two columns, adjacent in the row direction, are connected in a zigzag manner in the column direction by the first signal line and the third signal line, respectively.
(12)
The display device according to (4), in which
the multiple signal lines include:
multiple first signal lines connected to the light emitting diode elements of the first color;
multiple second signal lines connected to the light emitting diode elements of the second color; and
multiple third signal lines connected to the light emitting diode elements of the third color,
the light emitting diode elements of the first color respectively included in two pixels, adjacent in the row direction, share one of the first signal lines,
the light emitting diode elements of the second color respectively included in the two pixels are connected to the second signal lines different from each other, respectively, and
the light emitting diode element of the third color included in one pixel of the two pixels is connected to one of the third signal lines, whereas the light emitting diode element of the third color included in another pixel of the two pixels is not connected to the third signal line.
(13)
The display device according to claim (4), in which
the light emitting diode elements of the first color included in two pixels adjacent in the row direction share one of the first signal lines, and
the light emitting diode elements of the third color included in two pixels adjacent in an oblique direction between the row direction and the column direction share one of the third signal lines.
(14)
The display device according to any one of (2) to (13), further including:
a first resistor connected in series to the light emitting diode element of the first color; and
a second resistor connected in series to the light emitting diode element of the third color.
(15)
The display device according to (14), in which a resistance value of the first resistor and a resistance value of the second resistor are each independently in a range of 0.1 V/(LED current value [A]) Ω or more and 0.3 V/(LED current value [A]) Ω or less.
(16)
The display device according to (14) or (15), in which the first resistor and the second resistor are a first resistance element and a second resistance element, respectively.
(17)
The display device according to (14) or (15), in which
the first resistor is a contact resistance of a joint portion to which an anode of the light emitting diode element of the first color is joined, and
the second resistor is a contact resistance of a joint portion to which an anode of the light emitting diode element of the third color is joined.
(18)
The display device according to (5), in which a ratio of a width of the signal line connected to the red light emitting diode element to a width of the signal line connected to the green light emitting diode element is 1.7 or more and 2.3 or less.
(19)
The display device according to any one of (1) to (18), further including
multiple packages provided on the substrate,
in which the pixel is provided in the package.
(20)
A display device including:
a substrate;
multiple pixels that are provided on the substrate and form multiple columns; and
multiple signal lines that are provided on the substrate and extend in a column direction,
in which the multiple pixels include at least one of multiple first pixels including light sources of three colors or multiple second pixels including light sources of two colors,
the light sources of the two colors respectively include light emitting diode elements,
the light sources of the three colors respectively include light emitting diode elements, and
a number of the signal lines is two per column.

### REFERENCE SIGNS LIST

10A, 10B, 10C, 110 Display device
11 Substrate
12, 12A, 12B, 13, 14, 15 SMD
20R Red LED element
20G Green LED element
20B Blue LED element
20W White LED element
20RL Red light source
20GL Green light source
20BL Blue light source
20RF Red filter
20GF Green filter
20BF Blue filter
20RQ, 20GQ Color conversion layer
21, 21A, 21B Pixel
22, 22A, 22B, 25 Package
23R, 23AR, 23BR, 23G, 23G1, 23G2, 23AG, 23BG, 23B, 23AB, 23BB Anode terminal
23GT, 23GT1, 23GT2, 23AGT, 23BGT Cathode terminal
24R, 24B Resistance element
Sₘ(R), Sₘ(G), Sₘ(B) Signal line
Gₙ Scanning line

What is claimed is:

1. A display device comprising:
a substrate;
multiple pixels that are provided on the substrate and form multiple columns; and
multiple signal lines that are provided on the substrate and extend in a column direction,
wherein the multiple pixels include at least one of multiple first pixels having light emitting diode elements of three colors or multiple second pixels having light emitting diode elements of two colors, and
a number of the signal lines is two per column.

2. The display device according to claim 1, wherein
the multiple pixels include the multiple first pixels, and
the first pixel includes a light emitting diode element of a first color, a light emitting diode element of a second color, and a light emitting diode element of a third color.

3. The display device according to claim 1, wherein
the multiple pixels include the multiple second pixels,
the multiple second pixels are arranged in a matrix,
the multiple second pixels include multiple third pixels and multiple fourth pixels,
the third pixel includes a light emitting diode element of a first color and a light emitting diode element of a second color,
the fourth pixel includes a light emitting diode element of the second color and a light emitting diode element of a third color, and
the third pixels and the fourth pixels are alternately arranged in the column direction and alternately arranged in a row direction.

4. The display device according to claim 1, wherein
the multiple pixels include the multiple first pixels and the multiple second pixels,
the multiple pixels are arranged in a matrix,
the first pixel includes a light emitting diode element of a first color, a light emitting diode element of a second color, and a light emitting diode element of a third color,
the second pixel includes a light emitting diode element of the first color and a light emitting diode element of the second color, and
the first pixels and the second pixels are alternately arranged in the column direction and alternately arranged in a row direction.

5. The display device according to claim 2, wherein
the light emitting diode element of the first color is a red light emitting diode element,
the light emitting diode element of the second color is a green light emitting diode element, and
the light emitting diode element of the third color is a blue light emitting diode element.

6. The display device according to claim 2, wherein the light emitting diode element of the second color has a highest luminance among the light emitting diode element of the first color, the light emitting diode element of the second color, and the light emitting diode element of the third color in a case where white display is performed.

7. The display device according to claim 6, wherein
the multiple signal lines include:
multiple first signal lines connected to the light emitting diode elements of the first color;
multiple second signal lines connected to the light emitting diode elements of the second color; and
multiple third signal lines connected to the light emitting diode elements of the third color,
a number of the first signal lines is one per column,
a number of the second signal lines is one per two columns, and
a number of the third signal lines is one per two columns.

8. The display device according to claim 7, wherein first pairs each including the first signal line and the second signal line and second pairs each including the second signal line and the third signal line are alternately arranged in a row direction.

9. The display device according to claim 7, wherein
the light emitting diode elements of the first color respectively included in two pixels, adjacent in a row direction, share one of the first signal lines, and
the light emitting diode elements of the third color respectively included in the two pixels share one of the third signal lines.

10. The display device according to claim 7, wherein
the light emitting diode element of the first color included in one pixel of two pixels, adjacent in a row direction, is connected to the first signal line, whereas the light emitting diode element of the first color included in another pixel of the two pixels is not connected to the first signal line, and
the light emitting diode element of the third color included in the one pixel of the two pixels is not connected to the third signal line, whereas the light emitting diode element of the third color included in the another pixel of the two pixels is connected to the third signal line.

11. The display device according to claim 10, wherein
the multiple pixels are arranged in a matrix, and
the light emitting diode elements of the first color and the light emitting diode elements of the third color included in two columns, adjacent in the row direction, are connected in a zigzag manner in the column direction by the first signal line and the third signal line, respectively.

12. The display device according to claim 4, wherein
the multiple signal lines include:
multiple first signal lines connected to the light emitting diode elements of the first color;
multiple second signal lines connected to the light emitting diode elements of the second color; and
multiple third signal lines connected to the light emitting diode elements of the third color,
the light emitting diode elements of the first color respectively included in two pixels, adjacent in the row direction, share one of the first signal lines,
the light emitting diode elements of the second color respectively included in the two pixels are connected to the second signal lines different from each other, respectively, and
the light emitting diode element of the third color included in one pixel of the two pixels is connected to one of the third signal lines, whereas the light emitting diode element of the third color included in another pixel of the two pixels is not connected to the third signal line.

13. The display device according to claim 3, wherein
the multiple signal lines include:
multiple first signal lines connected to the light emitting diode elements of the first color;
multiple second signal lines connected to the light emitting diode elements of the second color; and
multiple third signal lines connected to the light emitting diode elements of the third color,
the light emitting diode elements of the first color included in two pixels, adjacent in an oblique direction between the row direction and the column direction, share one of the first signal lines, and
the light emitting diode elements of the third color included in two pixels, adjacent in an oblique direction between the row direction and the column direction, share one of the third signal lines.

14. The display device according to claim 2, further comprising:
a first resistor connected in series to the light emitting diode element of the first color; and
a second resistor connected in series to the light emitting diode element of the third color.

15. The display device according to claim 14, wherein a resistance value of the first resistor and a resistance value of the second resistor are each independently in a range of 0.1 V/(LED current value [A]) Ω or more and 0.3 V/(LED current value [A]) Ω or less.

16. The display device according to claim 14, wherein the first resistor and the second resistor are a first resistance element and a second resistance element, respectively.

17. The display device according to claim 14, wherein
the first resistor is a contact resistance of a joint portion to which an anode of the light emitting diode element of the first color is joined, and
the second resistor is a contact resistance of a joint portion to which an anode of the light emitting diode element of the third color is joined.

18. The display device according to claim 5, wherein a ratio of a width of the signal line connected to the red light emitting diode element to a width of the signal line connected to the green light emitting diode element is 1.7 or more and 2.3 or less.

19. The display device according to claim 1, further comprising
multiple packages provided on the substrate,
wherein the pixel is provided in the package.

20. A display device comprising:
a substrate;
multiple pixels that are provided on the substrate and form multiple columns; and
multiple signal lines that are provided on the substrate and extend in a column direction,
wherein the multiple pixels include at least one of multiple first pixels including light sources of three colors or multiple second pixels including light sources of two colors,
the light sources of the two colors respectively include light emitting diode elements,
the light sources of the three colors respectively include light emitting diode elements, and
a number of the signal lines is two per column.
